(19) United States
(12) Patent Application Publication
(10) Pub. No.: US 2017/0292445 A1
(43) Pub. Date: Oct. 12, 2017

(54) INTERNAL COMBUSTION ENGINE COMPONENTS WITH ANTI-FOULING PROPERTIES AND METHODS OF MAKING SAME

(71) Applicant: 3M INNOVATIVE PROPERTIES COMPANY, St. Paul, MN (US)

(72) Inventors: Michael E. Nelson, Woodbury, MN (US); Moses M. David, Woodbury, MN (US); Ryan C. Shirk, Mendota Heights, MN (US)

(21) Appl. No.: 15/511,251

(22) PCT Filed: Sep. 22, 2015
(86) PCT No.: PCT/US2015/051326

§ 371 Date: Mar. 15, 2017

Related U.S. Application Data
(60) Provisional application No. 62/053,486, filed on Sep. 22, 2014.

(51) Int. Cl. F02B 77/02; C23C 16/02; C23C 16/513

(52) U.S. Cl. CPC F02B 77/02; C23C 16/513; C23C 16/0245

(57) ABSTRACT

A component of an internal combustion engine with anti-fouling (e.g., anti-coking) properties, said component comprising a metal surface; a plasma deposition formed layer comprising silicon, oxygen, and hydrogen on at least a portion of said metal surface; and an anti-fouling coating, of an at least partially fluorinated composition comprising at least one silane group, on at least a portion of a surface of said layer.

### BACKGROUND

In the past, various efforts have been made to impart anti-fouling (e.g., anti-coking) properties to a portion of an internal combustion engine. Despite such efforts, there continues to be a need for improved ways of imparting anti-fouling properties to components of an internal combustion engine.

### SUMMARY

In one aspect of the present invention, a component of an internal combustion engine is provided with anti-fouling (e.g., anti-coking) properties. The component comprises a metal surface; a plasma deposition formed layer comprising silicon, oxygen, and hydrogen on at least a portion of said metal surface; and an anti-fouling coating, of an at least partially fluorinated composition comprising at least one silane group, on at least a portion of a surface of said layer.

In a further aspect of the present invention, a component of an internal combustion engine is provided with anti-fouling properties, where the anti-fouling coating comprises a hexafluoropropylene oxide derived silane polymer having a molecular weight of greater than about 5500, with the anti-fouling coating having (a) a water contact angle that decreases by less than about 27% after 10000 abrasion cycles, (b) a thickness of between about 2 and about 15 nanometers, and (c) a coefficient of friction constant of less than about 0.35.

In another aspect of the present invention, an internal combustion engine is provided that comprises a component with anti-fouling properties in accordance with the present invention.

In an additional aspect of the present invention, a method is provided for making a component of an internal combustion engine with anti-fouling (e.g., anti-coking) properties. The method comprises: forming a layer comprising silicon, oxygen, and hydrogen on at least a portion of the metal surface of the component by plasma deposition; and applying an at least partially fluorinated composition comprising at least one silane group to at least a portion of a surface of the layer comprising the silicon, oxygen, and hydrogen.

As used herein, the terms “alkyl” and the prefix “alk” are inclusive of both straight chain and branched chain groups and of cyclic groups, e.g., cycloalkyl. Unless otherwise specified, these groups contain from 1 to 20 carbon atoms. In some embodiments, these groups have a total of up to 10 carbon atoms, up to 8 carbon atoms, up to 6 carbon atoms, or up to 4 carbon atoms.

Cyclic groups can be monocyclic or polycyclic and preferably have from 3 to 10 ring carbon atoms.

The term “alkylene” is the divalent form of the “alkyl” groups defined above.

Unless otherwise indicated, the term “halogen” refers to a halogen atom or one or more halogen atoms, including chlorine, bromine, iodine, and fluorine atoms.

The term “aryl” as used herein includes carbocyclic aromatic rings or ring systems optionally containing at least one heteroatom. Examples of aryl groups include phenyl, naphthyl, biphenyl, and pyridinyl.

The term “arylene” is the divalent form of the “aryl” groups defined above.

The term “carbamate” refers to the group —O—C(O)—N(R)— wherein R is as defined above.

The term “ureylene” refers to the group —N(R)—C(O)—N(R)— wherein R is as defined above.

The term “substituted aryl” refers to an aryl group as defined above, which is substituted by one or more substituents independently selected from the group consisting of C₁₋₄ alkyl, C₁₋₄ alkoxy, halogen, hydroxy, amino, and nitro.

As used herein, “a,” “an,” “the,” “at least one,” and “one or more” are used interchangeably.

Also herein, the recitations of numerical ranges by endpoints include all numbers subsumed within that range, including the endpoints (e.g., 1 to 5 includes 1, 1.5, 2, 2.75, 3, 3.80, 4, 5, etc.). When the number is an integer, then only the whole numbers are included (e.g., 1, 2, 3, 4, 5, etc.).

The above summary of the present invention is not intended to describe each disclosed embodiment or every implementation of the present invention. The description that follows more particularly exemplifies illustrative embodiments. In several places throughout the application, guidance is provided through lists of examples, which examples can be used individually and in various combinations. In each instance, the recited list serves only as a representative group and should not be interpreted as an exclusive list.

### BRIEF DESCRIPTION OF THE DRAWING

The following figures illustrate various exemplary internal combustion engine components that may be suitable for use with the present invention.

FIG. 1 is a cross-sectioned side view of an exemplary port fuel injected (PFI) spark ignited dual intake valve combustion chamber, with a spark plug and fuel injectors.

FIG. 2 is a partial cross-sectional side view of an exemplary PFI spark ignited single intake valve combustion chamber and fuel injector;

FIG. 3A is a photograph of the outlet surface of a used gasoline direct injection (GDI) injector nozzle that was not coated with an anti-fouling coating, according to the present invention, and that exhibits coking build-up.

FIG. 3B is a photograph of the outlet surface of a used GDI injector nozzle that was pre-coated with an anti-fouling coating, according to the present invention, before the nozzle was used and that exhibits a reduced presence of coking build-up.

FIG. 4 is a photograph of an oil coated inlet side of the intake valves and manifold of a used spark ignited combustion chamber that was not coated with an anti-fouling coating, according to the present invention, and that exhibits coking build-up.

FIG. 5 is a photograph of a used intake valve that was not coated with an anti-fouling coating, according to the present invention, and that exhibits coking build-up.

FIG. 6 is a photograph of the combustion chambers of a disassembled used compression ignition engine that was not coated with an anti-fouling coating, according to the present invention, and that exhibits coking build-up.

FIG. 7 is a photograph of a used exhaust gas recirculation (EGR) valve that was not coated with an anti-fouling coating, according to the present invention, and that exhibits coking build-up.

FIG. 8 is a photograph of the used piston tops of a four cylinder engine block that was not coated with an anti-fouling coating, according to the present invention, and that exhibits coking build-up on the tops of the pistons.

FIG. 9 is a photograph of a used piston top that was not coated with an anti-fouling coating, according to the present invention, and that exhibits coking build-up on the top of the piston.

FIG. 10 is a photograph of the rocker arms for a used internal combustion engine that were not coated with an anti-fouling coating, according to the present invention, and that exhibit coking build-up.

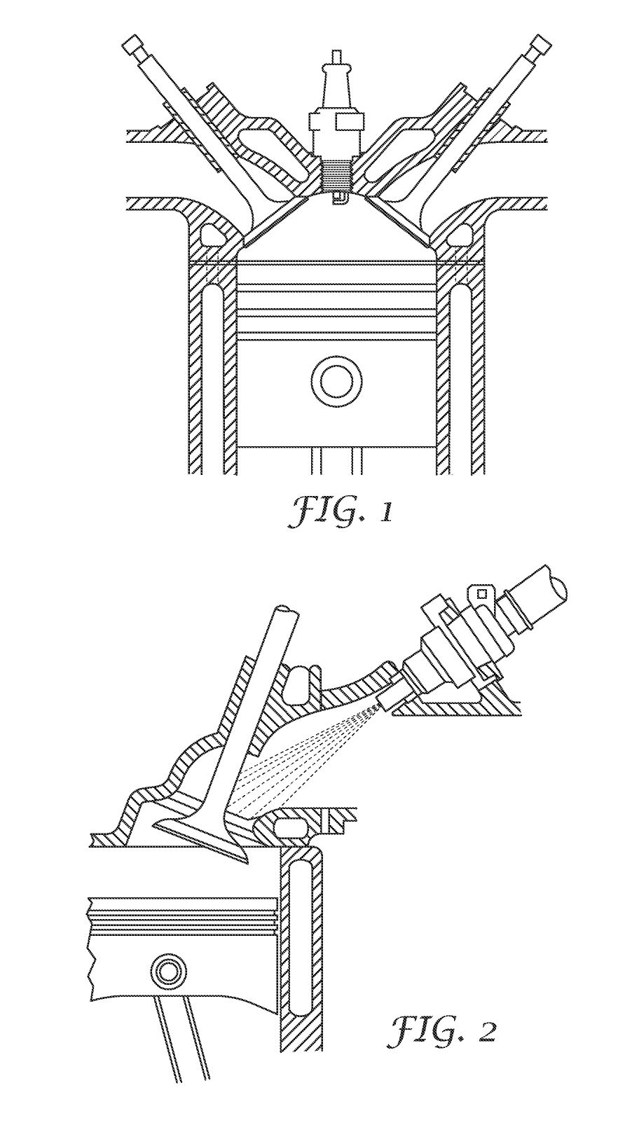

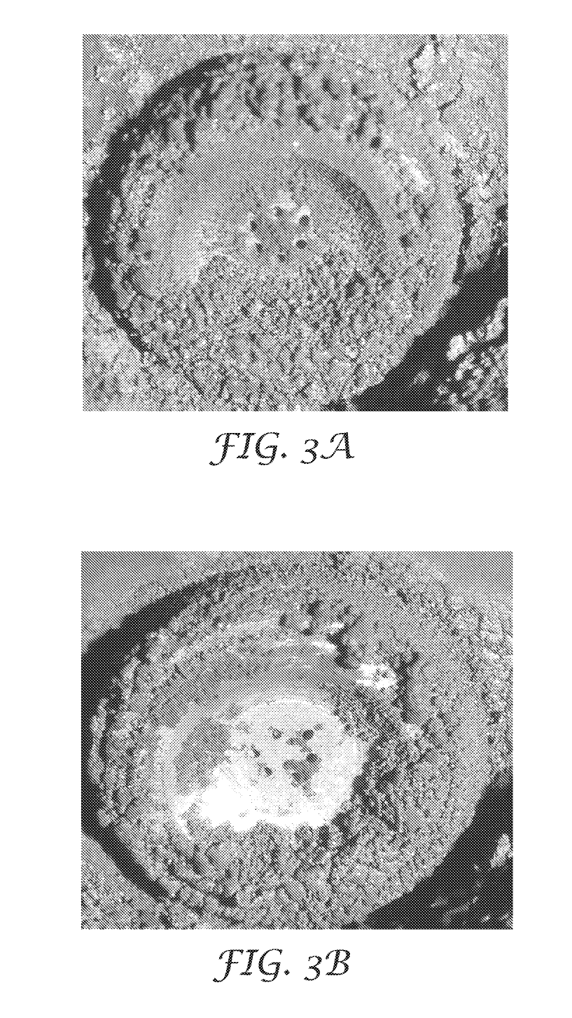

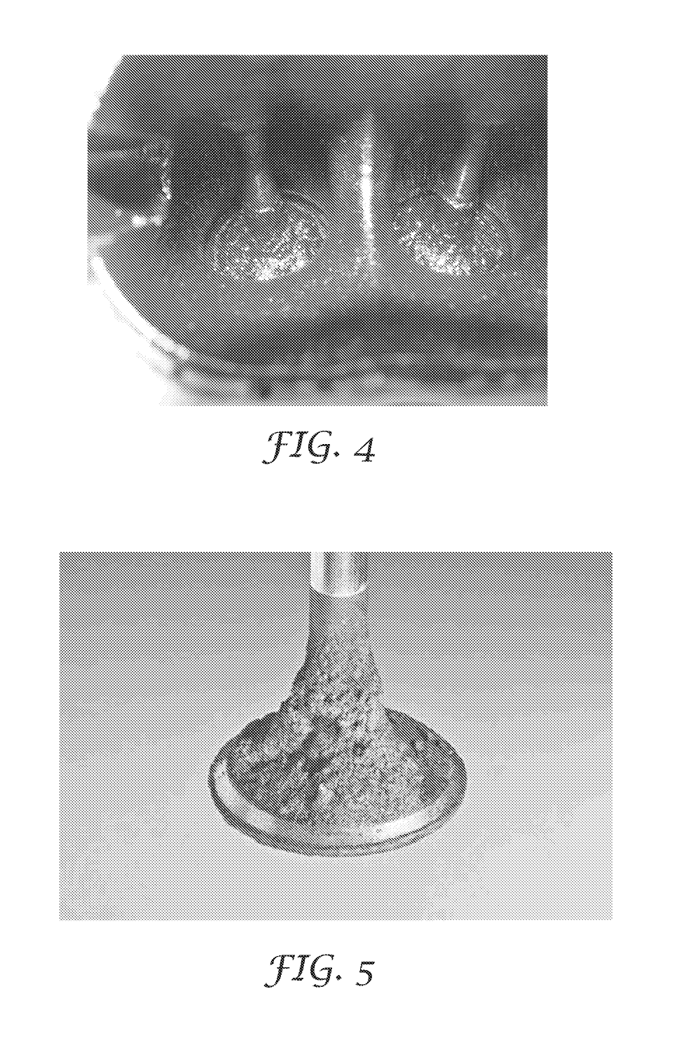

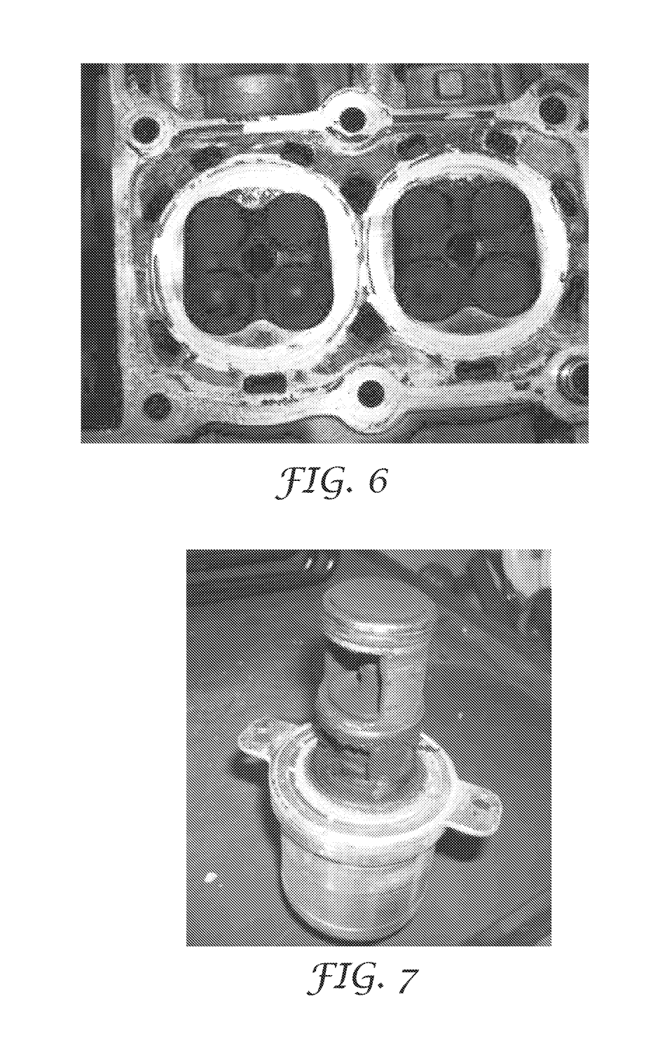

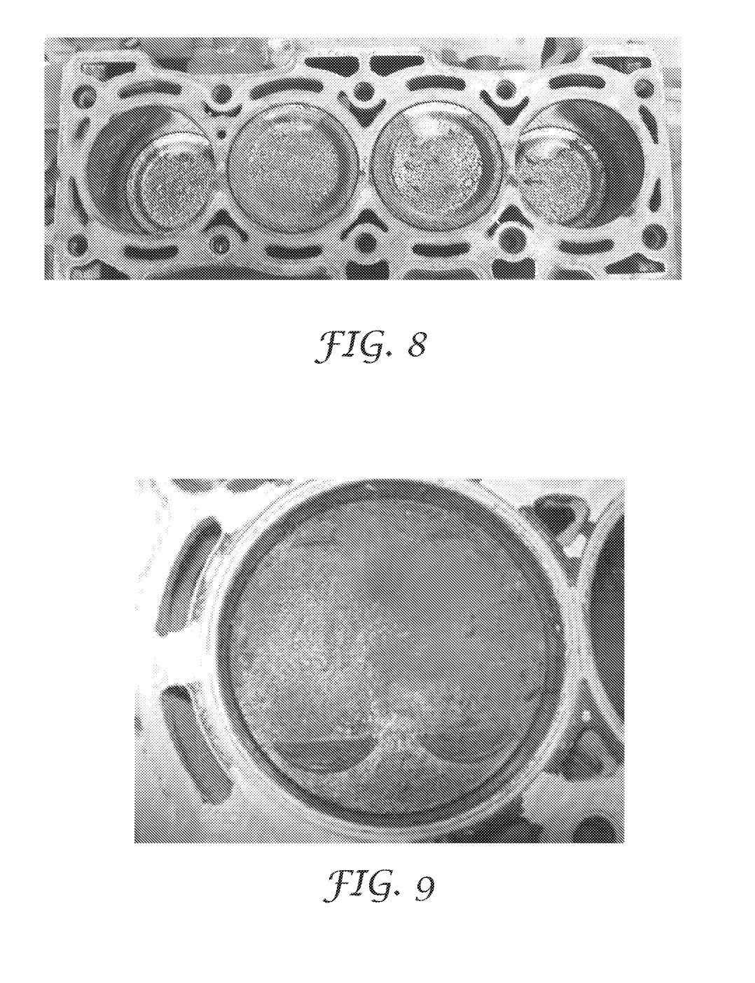

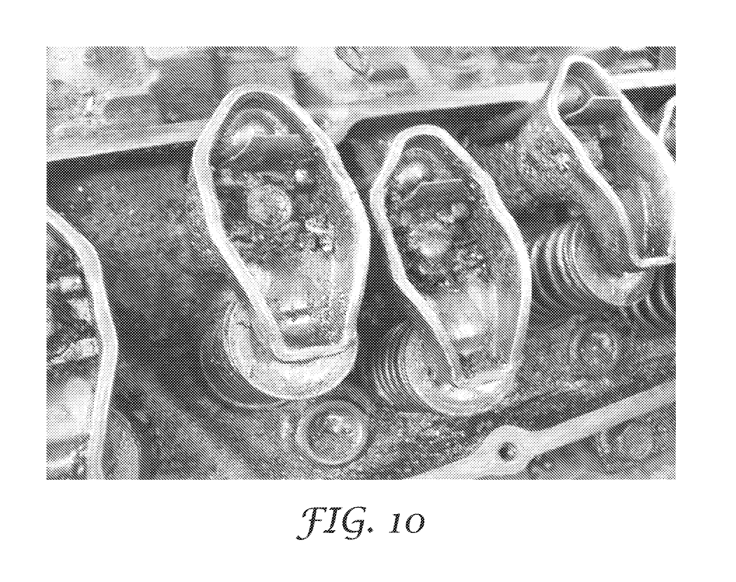

### DETAILED DESCRIPTION OF ILLUSTRATIVE EMBODIMENTS OF THE INVENTION

A component of an internal combustion engine according to the present invention includes at least one portion thereof having anti-fouling (e.g., anti-coking) properties. The component comprises: a metal surface; a plasma deposition formed layer comprising silicon, oxygen, and hydrogen on at least a portion of said metal surface; and an anti-fouling coating, of an at least partially fluorinated composition comprising at least one silane group, on at least a portion of a surface of said layer. Exemplary internal combustion engine components that may benefit from the present invention include fuel injector nozzles, fuel injector bodies, surfaces (e.g., backside) of an intake valve, intake tracts, surfaces (e.g., backside) of an exhaust valve, valvetrain components, exhaust head tracts, cooling systems (e.g., cooling passages), oil passages (e.g., oil lines, turbo oil lines, etc.), piston crowns, piston bowls, combustion chambers, EGR components (e.g., EGR valve, EGR line, etc.) air/oil separators, etc.

As used herein, a metal surface of the internal combustion engine component can be a surface of a metal portion of the component or a metalized surface (e.g., a metal coating) on a non-metal portion of the component, with the metal being in an elemental and/or alloyed form that is solid at room temperature. As used herein, the term “substrate” refers to the internal combustion engine component and “metal or metallized substrate” refers to the metal surface of the component.

For certain embodiments, the metal and/or metal alloy is selected from the group consisting of chromium, chromium alloys, iron, aluminum, copper, nickel, zinc, tin, stainless steel, and brass. For certain of these embodiments, the metal and/or metal alloy is chromium or stainless steel. A metal substrate comprises one or more metals and/or metal alloys at a major surface and one or more metals and/or metal alloys throughout the body of the substrate. For certain embodiments, a major surface of the metal substrate comprises chromium. A metallized substrate comprises one or more metals and or metal alloys at a major surface. The metallized substrate can further comprise a polymeric material, which includes one or both of thermoset and thermoplastic polymers, ceramic, glass, porcelain, as well as other materials capable of having a metallized surface. For certain embodiments, a major surface of the metallized substrate comprises chromium. Examples of metal or metallized substrates include, but are not limited to, kitchen and bathroom faucets, taps, handles, spouts, sinks, drains, hand rails, towel holders, curtain rods, dish washer panels, refrigerator panels, stove tops, stove, oven, and microwave panels, exhaust hoods, grills, metal wheels or rims, and the like.

Forming a layer comprising silicon, oxygen, and hydrogen on at least a portion of the surface of the substrate by plasma deposition can be carried out in a suitable reaction chamber having a capacitively-coupled system with at least one electrode powered by an RF (radio frequency) source and at least one grounded electrode, such as those described in U.S. Pat. No. 6,696,157 (David et al.) and U.S. Pat. No. 6,878,419 (David et al.). The FIG. 1 illustrates a parallel plate apparatus 10 suitable for the plasma deposition, showing a grounded chamber 12 from which air is removed by a pumping stack (not shown). The gas or gases to form the plasma are injected radially inward through the reactor wall to an exit pumping port in the center of the chamber. Substrate 14 is positioned proximate RF-powered electrode 16. Electrode 16 is insulated from chamber 12 by a polytetrafluoroethylene support 18.

The substrate to be treated may by pre-cleaned by methods known to the art to remove contaminants that may interfere with the plasma deposition. One useful pre-cleaning method is exposure to an oxygen plasma. For this pre-cleaning, pressures in the chamber are maintained between 1.3 Pa (10 mTorr) and 27 Pa (200 mTorr). Plasma is generated with RF power levels of between 500 W and 3000 W.

A solvent washing step with an organic solvent such as acetone or ethanol may also be included prior to the exposure to an oxygen plasma.

The substrate is located on the powered electrode in the chamber, and the chamber is evacuated to the extent necessary to remove air and any impurities. This may be accomplished by vacuum pumps at a pumping stack connected to the chamber. A source gas is introduced into the chamber at a desired flow rate, which depends on the size of the reactor, the surface area of the electrodes, and the surface area of the substrate. The gas is oxygen when pre-cleaning is carried out in an oxygen plasma. During plasma deposition, the gas includes an organosilicon and/or a silane compound, and the flow rates are sufficient to establish a suitable pressure at which to carry out plasma deposition, typically 0.13 Pa to 130 Pa (0.001 Torr to 1.0 Torr). For a cylindrical reactor that has an inner diameter of approximately 55 cm and a height of approximately 20 cm, the flow rates are typically from about 50 to about 500 standard cubic centimeters per minute (sccm). At the pressures and temperatures (less than about 50° C.) of the plasma deposition, the gas remains in the vapor form. An RF electric field is applied to the powered electrode, ionizing the gas and establishing a plasma. In the RF-generated plasma, energy is coupled into the plasma through electrons. The plasma acts as the charge carrier between the electrodes. The plasma can fill the entire reaction chamber and is typically visible as a colored cloud.

The plasma also forms an ion sheath proximate at least one electrode. The ion sheath typically appears as a darker area around the electrode. Within the ion sheath, ions accelerating toward the electrode bombard the species being deposited from the plasma onto the substrate. The depth of the ion sheath normally ranges from about 1 mm to about 50 mm and depends on factors such as the type and concentration of gas used, pressure in the chamber, the spacing between the electrodes, and relative size of the electrodes. For example, reduced pressures will increase the size of the ion sheath. When the electrodes are different sizes, a larger, stronger ion sheath will form around the smaller electrode. Generally, the larger the difference in electrode size, the larger the difference in the size of the ion sheaths, and increasing the voltage across the ion sheath will increase ion bombardment energy.

The substrate is exposed to the ion bombarded species being deposited from the plasma. The resulting reactive species within the plasma react on the surface of the substrate, forming a layer, the composition of which is controlled by the composition of the gas being ionized in the plasma. The species forming the layer can attach to the surface of the substrate by covalent bonds, and therefore the layer can be covalently bonded to the substrate.

For certain embodiments, forming the layer comprising the silicon, oxygen, and hydrogen comprises ionizing a gas comprising at least one of an organosilicon or a silane compound. For certain of these embodiments, the silicon of the at least one of an organosilicon or a silane compound is present in an amount of at least about 5 atomic percent of the gas mixture. Thus, if a reactive gas such as oxygen or an inert gas such as argon are mixed along with the organosilicon or silane precursor, the atomic percent of silicon in the gas mixture is calculated based on the volumetric (or molar) flow rates of the component gases in the mixture. For certain of these embodiments, the gas comprises the organosilicon. For certain of these embodiments, the organosilicon comprises at least one of trimethylsilane, triethylsilane, trimethoxysilane, triethoxysilane, tetramethylsilane, tetraethylsilane, tetramethoxysilane, tetraethoxysilane, hexamethylcyclotrisiloxane, tetramethylcyclotetrasiloxane, tetraethylcyclotetrasiloxane, octamethylcyclotetrasiloxane, hexamethyldisiloxane, and bistrimethylsilylmethane. For certain of these embodiments, the organosilicon comprises tetramethylsilane. In addition to or alternatively, for certain of these embodiments, the gas comprises the silane compound. For certain of these embodiments, the silane compound comprises one or more of SiH₄ (silicon tetrahydride), Si₂H₆ (disilane), and SiClH₃ (chlorosilane). For certain of these embodiments, the silane compound comprises SiH₄ (silicon tetrahydride).

For certain embodiments, including any one of the above embodiments, preferably the gas further comprises oxygen.

For certain embodiments, including any one of the above embodiments, the gas further comprises at least one of argon, ammonia, hydrogen, and nitrogen. Each additional gas can be added separately or in combination with each other. For certain of these embodiments, the gas further comprises at least one of ammonia, hydrogen, and nitrogen such that the total amount of the at least one of ammonia, hydrogen, and nitrogen is at least about 5 molar percent and not more than about 50 molar percent of the gas.

Plasma deposition of the layer typically occurs at a rate ranging from about 1 to about 100 nm/second. The rate will depend on conditions including pressure, power, concentration of gas, types of gases, relative size of the electrodes, and so on. In general, the deposition rate increases with increasing power, pressure, and concentration of gas, although the rate can approach an upper limit.

For certain embodiments, including any one of the above embodiments, the plasma deposition of the layer comprising the silicon, oxygen, and hydrogen is carried out for a period of time not less than about 2 seconds, not less than about 5 seconds, or not less than about 10 seconds.

For certain embodiments, including any one of the above embodiments, the plasma deposition of the layer comprising the silicon, oxygen, and hydrogen is carried out for a period of time not more than about 30 seconds, about 20 seconds, or about 15 seconds.

For certain embodiments, including any one of the above embodiments, the plasma deposition of the layer comprising the silicon, oxygen, and hydrogen is carried out for a period of time not less than about 5 seconds and not more than about 15 seconds. For certain of these embodiments, the period of time is about 10 seconds.

For certain embodiments, the plasma deposition of the layer comprising the silicon, oxygen, and hydrogen is carried out for a period of time such that at least one of the color hue or the intensity of the color hue of the substrate is changed. For certain of these embodiments, the color hue of the substrate is changed to include an increase in a blue color hue as visually observed.

For certain embodiments, including any one of the above embodiments, the substrate is exposed to an oxygen plasma prior to the plasma deposition of the layer comprising the silicon, oxygen, and hydrogen.

After the layer comprising the silicon, oxygen, and hydrogen is formed by plasma deposition, the surface of the layer may be exposed to an oxygen plasma to form silanol groups or to form additional silanol groups on the surface of the layer. For this post-treatment, pressures in the chamber are maintained between 1.3 Pa (10 mTorr) and 27 Pa (200 mTorr). The oxygen plasma is generated with RF power levels of between about 50 W and about 3000 W.

For certain embodiments, including any one of the above embodiments, after its deposition is complete, the layer comprising the silicon, oxygen, and hydrogen is exposed to an oxygen plasma.

For certain embodiments, including any one of the above embodiments, the layer comprising silicon, oxygen, and hydrogen preferably further comprises carbon. The presence of the carbon can impart an increased flexibility and toughness to the layer.

As used herein, the “at least partially fluorinated composition comprising at least one silane group” refers to at least one of polyfluoropolyether silanes, perfluoroalkyl silanes, fluorinated oligomeric silanes, or swallow-tail silanes. In one embodiment, the at least partially fluorinated composition comprising at least one silane group is a polyfluoropolyether silane.

Polyfluoropolyether silanes are represented by the Formula I:

R_{f}{-Q-[SiY₃₋ₓ(R¹)ₓ]_{y}}_{z} I

wherein R_{f} is a monovalent or multivalent polyfluoropolyether segment; Q is an organic divalent or trivalent linking group; each Y is independently a hydrolyzable group; R¹ is an alkyl group or a phenyl group; x is 0 or 1 or 2; y is 1 or 2, and z is 1, 2, 3, or 4.

The monovalent or multivalent polyfluoropolyether segment, R_{f}, includes linear, branched, and/or cyclic structures, that may be saturated or unsaturated, and includes two or more in-chain oxygen atoms. R_{f} is preferably a perfluorinated group (i.e., all C—H bonds are replaced by C—F bonds). However, hydrogen or chlorine atoms may be present instead of fluorine atoms provided that not more than one atom of either hydrogen or chlorine is present for every two carbon atoms. When hydrogen and/or chlorine are present, preferably, R_{f} includes at least one perfluoromethyl group.

The organic divalent or trivalent linking group, Q, can include linear, branched, or cyclic structures, that may be saturated or unsaturated. The organic divalent or trivalent linking group, Q, optionally contains one or more heteroatoms selected from the group consisting of sulfur, oxygen, and nitrogen, and/or optionally contains one or more functional groups selected from the group consisting of esters, amides, sulfonamides, carbonyl, carbonates, ureylenes, and carbamates. Q includes not less than 2 carbon atoms and not more than about 25 carbon atoms. Q is preferably substantially stable against hydrolysis. When more than one Q groups are present, the Q groups can be the same or different.

For certain embodiments, including any one of the above embodiments, Q includes organic linking groups such as —C(O)N(R)—(CH₂)ₖ—, —S(O)₂N(R)—(CH₂)ₖ—, —(CH₂)ₖ—, —CH₂O—(CH₂)ₖ—, —C(O)S—(CH₂)ₖ—, —CH₂OC(O)N(R)—(CH₂)ₖ—, and

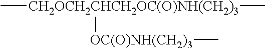

wherein R is hydrogen or C₁₋₄ alkyl, and k is 2 to about 25. For certain of these embodiments, k is 2 to about 15 or 2 to about 10.

The hydrolyzable groups, Y, may be the same or different and are capable of hydrolyzing, for example, in the presence of water, optionally under acidic or basic conditions, producing groups capable of undergoing a condensation reaction, for example silanol groups.

For certain embodiments, including any one of the above embodiments, the polyfluoropolyether silane is of the Formula Ia:

R_{f}[Q′-C(R)₂—Si(Y′)₃₋ₓ(R^{1a})ₓ]_{z} Ia

wherein:
R_{f} is a monovalent or multivalent polyfluoropolyether segment;
Q′ is an organic divalent linking group;
each R is independently hydrogen or a C₁₋₄ alkyl group;
each Y′ is a hydrolysable group independently selected from the group consisting of halogen, alkoxy, acyloxy, polyalkyleneoxy, and aryloxy groups;
R^{1a} is a C₁₋₈ alkyl or phenyl group;
x is 0 or 1 or 2; and
z is 1, 2, 3, or 4.

For certain embodiments, including any one of the above embodiments of Formulas I or Ia, the monovalent or multivalent polyfluoropolyether segment, R_{f}, comprises perfluorinated repeating units selected from the group consisting of —(CF₂ₙ)—, —(CₙF₂ₙO)—, —(CF(Z))—, —(CF(Z)O)—, —(CF(Z)CₙF₂ₙO)—, —(CF₂ₙCF(Z)O)—, —(CF₂CF(Z)O)—, and combinations thereof; Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted; and n is an integer from 1 to 12. Being oligomeric or polymeric in nature, these compounds exist as mixtures and are suitable for use as such. The perfluorinated repeating units may be arranged randomly, in blocks, or in an alternating sequence. For certain of these embodiments, the polyfluoropolyether segment comprises perfluorinated repeating units selected from the group consisting of —(CₙF₂ₙO)—, —(CF(Z)O)—, —(CF(Z)CₙF₂ₙO)—, —(CₙF₂ₙCF(Z)O)—, —(CF₂CF(Z)O)—, and combinations thereof. For certain of these embodiments, n is an integer from 1 to 12, 1 to 6, 1 to 4, or 1 to 3.

For certain embodiments, including any one of the above embodiments, R_{f} is monovalent, and z is 1. For certain of these embodiments, R_{f} is terminated with a group selected from the group consisting of CₙF₂ₙ₊₁—, CₙF₂ₙ₊₁O—, and X′CₙF₂ₙO— wherein X′ is a hydrogen or chlorine atom. For certain of these embodiments, the terminal group is CₙF₂ₙ+1- or CₙF₂ₙ₊₁O— wherein n is an integer from 1 to 6 or 1 to 3. For certain of these embodiments, the approximate average structure of R_{f} is C₃F₇O(CF(CF₃)CF₂O)ₚCF(CF₃)— or CF₃O(C₂F₄O)ₚCF₂— wherein the average value of p is 3 to 50.

For certain embodiments, including any one of the above embodiments except where R_{f} is monovalent, R_{f} is divalent, and z is 2. For certain of these embodiments, R_{f} is selected from the group consisting of —CF₂O(CF₂O)ₘ(C₂F₄O)ₚCF₂—, —CF(CF₃)—(OCF₂CF(CF₃))ₚO—R_{f}′—O(CF(CF₃)CF₂O)ₚCF(CF₃)—, —CF₂O(C₂F₄O)ₚCF₂—, and —(CF₂)₃O(C₄F₈O)ₚ(CF₂)₃—, and wherein R_{f}′ is a divalent, perfluoroalkylene group containing at least one carbon atom and optionally interrupted in chain by O or N, m is 1 to 50, and p is 3 to 40. For certain of these embodiments, R_{f}′ is (C F₂ₙ), wherein n is 2 to 4. For certain of these embodiments, R_{f} is selected from the group consisting of —CF₂O(CF₂O)ₘ(C₂F₄O)ₚCF₂—, —CF₂O(C₂F₄O)ₚCF₂—, and —CF(CF₃)—(OCF₂CF(CF₃))ₚO—(CₙF₂ₙ)—O(CF(CF₃)CF₂O)ₚCF(CF₃)—, and wherein n is 2 to 4, and the average value of m+p or p+p or p is from about 4 to about 24.

The above described polyfluoropolyether silanes typically include a distribution of oligomers and/or polymers, so p and m may be non-integral. The above structures are approximate average structures where the approximate average is over this distribution. These distributions may also contain perfluoropolyethers with no silane groups or more than two silane groups. Typically, distributions containing less than about 10% by weight of compounds without silane groups can be used.

For certain embodiments, including any one of the above embodiments where the organic divalent linking group, Q′ is present, Q′ is a saturated or unsaturated hydrocarbon group including 1 to about 15 carbon atoms and optionally containing 1 to 4 heteroatoms and/or 1 to 4 functional groups. For certain of these embodiments, Q′ is a linear hydrocarbon containing 1 to about 10 carbon atoms, optionally containing 1 to 4 heteroatoms and/or 1 to 4 functional groups. For certain of these embodiments, Q′ contains one functional group. For certain of these embodiments, Q′ is preferably —C(O)N(R)(CH₂)₂—, —OC(O)N(R)(CH₂)₂—, —CH₂O(CH₂)₂—, or —CH₂—OC(O)N(R)—(CH₂)₂—, wherein R is hydrogen or C₁₋₄ alkyl.

For certain embodiments, including any one of the above embodiments where R is present, R is hydrogen.

For certain embodiments, including any one of the above embodiments where the hydrolyzable group Y or Y′ is present, each Y or Y′ is independently a group such as halogen, alkoxy, acyloxy, aryloxy, and polyalkyleneoxy. Alkoxy is —OR′, and acyloxy is —OC(O)R′, wherein each R′ is independently a lower alkyl group, optionally substituted by one or more halogen atoms. For certain embodiments, R′ is preferably C₁₋₆ alkyl and more preferably C₁₋₄ alkyl. Aryloxy is —OR″ wherein R″ is aryl optionally substituted by one or more substituents independently selected from halogen atoms and C₁₋₄ alkyl optionally substituted by one or more halogen atoms. For certain embodiments, R″ is preferably unsubstituted or substituted C₆₋₁₂ aryl and more preferably unsubstituted or substituted C₆₋₁₀ aryl. Polyalkyleneoxy is —O—(CHR⁴—CH₂O)_{q}—R³ wherein R³ is C₁₋₄ alkyl, R⁴ is hydrogen or methyl, with at least 70% of R⁴ being hydrogen, and q is 1 to 40, preferably 2 to 10.

For certain embodiments, including any one of the above embodiments, x is 0.

For certain embodiments, the number average molecular weight of the polyfluoropolyether silane is about 750 to about 6000, preferably about 800 to about 4000.

For certain embodiments, including any one of the above embodiments, particularly of Formula Ia, R_{f} is —CF₂O(CF₂O)ₘ(C₂F₄O)ₚCF₂—, and Q′-C(R)₂—Si(Y′)₃₋ₓ(R^{1a})ₓ is C(O)NH(CH₂)₃Si(OR′)₃ wherein R′ is methyl or ethyl. For certain of these embodiments, m and p are each about 9 to 12.

The compounds of Formulas I and Ia described above can be synthesized using standard techniques. For example, commercially available or readily synthesized perfluoropolyether esters (or functional derivatives thereof) can be combined with a functionalized alkoxysilane, such as a 3-aminopropylalkoxysilane, according to U.S. Pat. No. 3,810,874 (Mitsch et al.). It will be understood that functional groups other than esters may be used with equal facility to incorporate silane groups into a perfluoropolyether.

Perfluoropolyether diesters, for example, may be prepared through direct fluorination of a hydrocarbon polyether diester. Direct fluorination involves contacting the hydrocarbon polyether diester with F₂ in a diluted form. The hydrogen atoms of the hydrocarbon polyether diester will be replaced with fluorine atoms, thereby generally resulting in the corresponding perfluoropolyether diester. Direct fluorination methods are disclosed in, for example, U.S. Pat. No. 5,578,278 (Fall et al.) and U.S. Pat. No. 5,658,962 (Moore et al.).

In another embodiment, the at least partially fluorinated composition comprising one or more a silane groups is a perfluoroalkyl silane of the following Formula II:

R²_{f}-Q²-SiX₃₋ₓR²ₓ II

wherein: R²_{f} is a perfluorinated group optionally containing one or more heteroatoms (for example, oxygen atoms); the connecting group Q² is a divalent alkylene group, arylene group, or mixture thereof, containing one or more heteroatoms (e.g., oxygen, nitrogen, or sulfur), or functional groups (e.g., carbonyl, amido, or sulfonamido), and containing about 2 to about 16 carbon atoms (preferably, about 3 to about 10 carbon atoms); R² is a lower alkyl group (e.g., a C₁₋₄ alkyl group, preferably, a methyl group); X is a halogen (for example, a chlorine atom), a lower alkoxy group (e.g., a C₁₋₄ alkoxy group, preferably, a methoxy or ethoxy group), or an acyloxy group (e.g., OC(O)R³, wherein R³ is a C₁₋₄ alkyl group); and x is 0 or 1. For certain embodiments, preferably x is 0. For certain of these embodiments, each X group is a lower alkoxy group. For certain of these embodiments, X is methoxy or ethoxy. Alternatively, the X groups include at least one acyloxy or halide group. For certain of these embodiments, each X is a halide, and for certain of these embodiments, each X is chloride.

For certain embodiments of Formula II, the perfluorinated group, R²_{f}, can include linear, branched, or cyclic structures, that may be saturated or unsaturated. For certain of these embodiments, R²_{f} is a perfluoroalkyl group (CₙF₂ₙ₊₁), wherein n is about 3 to about 20, more preferably, about 3 to about 12, and most preferably, about 3 to about 8. The divalent Q² group can include linear, branched, or cyclic structures, that may be saturated or unsaturated. For certain of these embodiments, the divalent Q² group is a linear group containing heteroatoms or functional groups, for example, as described above.

Typically, suitable fluorinated silanes include a mixture of isomers (e.g., a mixture of compounds containing linear and branched perfluoroalkyl groups). Mixtures of perfluoroalkyl silanes exhibiting different values of n can also be used.

For certain embodiments, the perfluoroalkyl silane includes any one or any combination of the following: C₃F₇CH₂OCH₂CH₂CH₂Si(OCH₃)₃; C₇F₁₅CH₂OCH₂CH₂CH₂Si(OCH₃)₃; C₇F₁₅CH₂OCH₂CH₂CH₂Si(OCH₂CH₃)₃; C₇F₁₅CH₂OCH₂CH₂CH₂Si(CH₃)(OCH₃)₂; C₇F₁₅CH₂OCH₂CH₂CH₂SiCl₃; C₇F₁₅CH₂OCH₂CH₂CH₂Si(CH₃)Cl₂; C₇F₁₅CH₂OCH₂CH₂CH₂SiCl(OCH₃)₂; C₇F₁₅CH₂OCH₂CH₂CH₂SiCl₂(OC₂H₅); C₇F₁₅C(O)NHCH₂CH₂CH₂Si(OCH₃)₃; CF₃(CF₂CF(CF₃))₃CF₂C(O)NHCH₂CH₂CH₂Si(OCH₂CH₃)₃; C₈F₁₇SO₂N(CH₂CH₃)CH₂CH₂CH₂Si(OCH₃)₃; C₈F₁₇SO₂N(CH₂CH₃)CH₂CH₂CH₂Si(OCH₂CH₃)₃; C₄F₉SO₂N(CH₃)CH₂CH₂CH₂Si(OCH₃)₃; C₈F₁₇CH₂CH₂Si(OCH₃)₃; C₆F₁₃CH₂CH₂Si(OCH₂CH₃)₃; C₈F₁₇CH₂CH₂Si(OCH₂CH₃)₃; C₈F₁₇SO₂N(CH₂CH₃)CH₂CH₂CH₂SiCl₃; C₈F₁₇SO₂N(CH₃)CH₂CH₂CH₂Si(CH₃)Cl₂; and C₈F₁₇CH₂OCH₂CH₂CH₂Si(OAc)₃.

Methods of making perfluoroalkyl silanes of the Formula II are known. See, for example, U.S. Pat. No. 5,274,159 (Pellerite et al.).

In another embodiment, the at least partially fluorinated composition comprising at least one silane group is a fluorinated oligomeric silane of the Formula III:

A-M^{f}ₙM^{h}ₘM^{a}ᵣ-G III

wherein A represents hydrogen or the residue of an initiating species (i.e., an organic compound having a radical and that derives from the decomposition of a free radical initiator or that derives from a chain transfer agent);

M^{f} represents units derived from one or more fluorinated monomers;

M^{h} represents units derived from one or more non-fluorinated monomers;

M^{a} represents units having a silyl group represented by the formula SiY″₃

wherein each Y″ independently represents an alkyl group, an aryl group, or a hydrolyzable group as defined above; and

G is a monovalent organic group comprising the residue of a chain transfer agent, and having the formula: —S-Q″-SiY₃;

wherein Q″ is an organic divalent linking group as defined below, and

each Y is independently a hydrolyzable group according to any one of the above definitions of Y.

The total number of units represented by the sum of n, m, and r is generally at least 2 and preferably at least 3 so as to render the compound oligomeric. The value of n in the fluorinated oligomeric silane is between 1 and 100 and preferably between 1 and 20. The values of m and r are between 0 and 100 and preferably between 0 and 20. According to a preferred embodiment, the value of m is less than that of n and n+m+r is at least 2.

The fluorinated oligomeric silanes typically have a number average molecular weight between 400 and 100000, preferably between 600 and 20000, more preferably between 1000 and 10000. The fluorinated oligomeric silanes preferably contains at least 5 mole % (based on total moles of units M^{f}, M^{h}, and M^{a}) of hydrolysable groups. When the units M^{h} and/or M^{a} are present the units M^{f}, M^{h}, and/or M^{a} may be randomly distributed.

It will further be appreciated by one skilled in the art that the preparation of fluorinated oligomeric silanes useful in the present invention results in a mixture of compounds and accordingly, general Formula III should be understood as representing a mixture of compounds whereby the indices n, m and r in Formula III represent the molar amounts of the corresponding unit in such mixture. Accordingly, it will be clear that n, m and r can be fractional values.

The units M^{f}ₙ of the fluorinated oligomeric silane are derived from fluorinated monomers, preferably fluorochemical acrylates and methacrylates.

Examples of fluorinated monomers for the preparation of the fluorinated oligomeric silane include those that can be represented by general formula:

R³_{f}-Q″-E

wherein R³_{f} represents a partially or fully fluorinated aliphatic group having at least 3 carbon atoms or a fluorinated polyether group, Q″ is a bond or an organic divalent linking group, and E represents an ethylenically unsaturated group. The ethylenically unsaturated group E can be fluorinated or non-fluorinated.

The partially or fully fluorinated aliphatic group, R³_{f}, in the fluorochemical monomer can be a fluorinated, preferably saturated, non-polar, monovalent aliphatic radical. It can be straight chain, branched chain, or cyclic or combinations thereof. It can contain heteroatoms such as oxygen, divalent or hexavalent sulfur, or nitrogen. R³ is preferably a fully-fluorinated radical, but hydrogen or chlorine atoms may be present if not more than one atom of either is present for every two carbon atoms. The R³ group has at least 2 and up to 18 carbon atoms, preferably 3 to 14, more preferably 4 to 10, especially 4. The terminal portion of the R³_{f} group is a perfluorinated moiety, which will preferably contain at least 7 fluorine atoms, e.g., CF₃CF₂CF₂— and (CF₃)₂CF—.

The preferred R³_{f} groups are fully or substantially fluorinated and are preferably those perfluoroalkyl groups of the formula CₙF₂ₙ₊₁— where n is 3 to 18, particularly 4 to 10. Compounds wherein the R³_{f} group is a C₄F₉— are generally more environmentally friendly than compounds where the R³_{f} group consists of a perfluorinated group with more carbon atoms.

The R³_{f} group can also be a perfluoropolyether group, which can be include linear, branched, and/or cyclic structures, that may be saturated or unsaturated, and substituted with one or more oxygen atoms. For certain embodiments, R³_{f} includes perfluorinated repeating units selected from the group consisting of —(CₙF₂ₙ)—, —(CₙF₂ₙO)—, —(CF(Z))—, —(CF(Z)O)—, —(CF(Z)CₙF₂ₙO)—, —(CₙF₂ₙCF(Z)O)—, —(CF₂CF(Z)O)—, and combinations thereof. For certain of these embodiments, Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted. For certain of these embodiments, R³_{f} is terminated with a group selected from the group consisting of CₙF₂ₙ₊₁—, CₙF₂ₙ₊₁O—, and X′CₙF₂ₙO—, wherein X′ is a hydrogen or chlorine atom. For certain of these embodiments, the terminal group is CₙF₂ₙ₊₁- or CₙF₂ₙ₊₁O—. In these repeating units or terminal groups, n is an integer of 1 or more. For certain embodiments, n is an integer from 1 to 12, 1 to 6, or preferably 1 to 4. For certain of these embodiments, the approximate average structure of R³_{f} is C₃F₇O(CF(CF₃)CF₂O)ₚCF(CF₃)— or CF₃O(C₂F₄O)ₚCF₂—, wherein the average value of p is 1 to about 50. As synthesized, these materials typically include a mixture of polymers. The approximate average structure is the approximate average of the mixture of polymers.

The linking group Q″ links the fluoroaliphatic or the fluorinated polyether group R³_{f} to the free radical polymerizable group E, and is a generally non-fluorinated organic linking groups. The linking group can be a chemical bond, but preferably contains from 1 to about 20 carbon atoms and may optionally contain oxygen, nitrogen, or sulfur-containing groups or a combination thereof. The linking group is preferably free of functional groups that substantially interfere with free-radical oligomerization (e.g., polymerizable olefinic double bonds, thiols, and other such functionality known to those skilled in the art). Examples of suitable organic divalent linking groups, Q″, include, for example, —C(O)Q^{a}-R⁵-Q^{b}-C(O)—, —C(O)O—CH₂—CH(OH)—R⁵-Q^{a}-C(O)—, -L¹-Q^{a}-C(O)NH-L²-, —R⁵-Q^{a}-C(O)—, —C(O)Q^{a}-R⁵, —R⁵—, —C(O)Q^{a}-R⁵-Q^{a}-, —S(O)₂NR—R⁵-Q^{a}-, —S(O)₂NR—R⁵—, and —S(O)₂NR—R⁵-Q^{a}-C(O)—, wherein Q^{a} and Q^{b} independently represent O or NR, R is hydrogen or C₁₋₄ alkyl, R⁵ represents a linear, cyclic or branched alkylene group that may be interrupted by one or more heteroatoms such as O or N, L¹ and L² each independently represent a non-fluorinated organic divalent linking group including an alkylene group, a carbonyl group, a carboxy amido alkylene group and/or a carboxy alkylene group. Preferred linking groups, Q″, include —S(O)₂N(R)—(CH₂)_{d}—OC(O)— and —(CH₂)_{d}—OC(O)—, where d is an integer from 1 to 20, preferably from 1 to 4.

Fluorochemical monomers R³_{f}-Q″-E as described above and methods for the preparation thereof are known and disclosed, e.g., in U.S. Pat. No. 2,803,615 (Ahlbrecht et al.). Examples of such compounds include general classes of fluorochemical acrylates, methacrylates, vinyl ethers, and allyl compounds containing fluorinated sulfonamido groups, acrylates or methacrylates derived from fluorochemical telomer alcohols, acrylates or methacrylates derived from fluorochemical carboxylic acids, and perfluoroalkyl acrylates or methacrylates as disclosed in European Patent No. 0 526 976, published Jan. 15, 1997.

Perfluoropolyether acrylates or methacrylates are described in U.S. Pat. No. 4,085,137 (Mitsch et al.).

Preferred examples of fluorinated monomers include:
CF₃(CF₂)₂CH₂OC(O)CH═CH₂, CF₃(CF₂)₂CH₂OC(O)C(CH₃)═CH₂,
CF₃(CF₂)₃CH₂OC(O)C(CH₃)═CH₂, CF₃(CF₂)₃CH₂OC(O)CH═CH₂,
CF₃(CF₂)₃S(O)₂N(R^{a})—(CH₂)₂—OC(O)CH═CH₂,
CF₃(CF₂)₃S(O)₂N(R^{a})—(CH₂)₂—OC(O)C(CH₃)═CH₂,
CF₃(CF₂)₃S(O)₂N(CH₃)—(CH₂)₂—OC(O)C(CH₃)═CH₂,
CF₃(CF₂)₃S(O)₂N(CH₃)—(CH₂)₂—OC(O)CH═CH₂,
CF₃CF₂(CF₂CF₂)₂₋₈(CH₂)₂OC(O)CH═CH₂,
CF₃(CF₂)₇(CH₂)₂OC(O)CH═CH₂, CF₃(CF₂)₇(CH₂)₂OC(O)C(CH₃)═CH₂, CF₃(CF₂)₇S(O)₂N(R^{a})—
(CH₂)₂—OC(O)CH═CH₂,
CF₃(CF₂)₇S(O)₂N(R^{a})—(CH₂)₂—OC(O)C(CH₃)═CH₂,
CF₃(CF₂)₇CH₂CH₂S(O)₂N(CH₃)—(CH₂)₂—OC(O)C(CH₃)═CH₂,
CF₃O(CF₂CF₂)CH₂OC(O)CH═CH₂, CF₃O(CF₂CF₂)CH₂OC(O)C(CH₃)═CH₂,
C₃F₇O(CF(CF₃)CF₂O)ᵤCF(CF₃)CH₂OC(O)CH═CH₂, and
C₃F₇O(CF(CF₃)CF₂O)CF(CF₃)CH₂OC(O)C(CH₃)═CH₂;

wherein R^{a} represents methyl, ethyl or n-butyl, and u is about 1 to 50.

The units M^{h} (when present) of the fluorinated oligomeric silane are generally derived from a non-fluorinated monomer, preferably a monomer consisting of a polymerizable group and a hydrocarbon moiety. Hydrocarbon group containing monomers are well known and generally commercially available. Examples of hydrocarbon containing monomers include those according to formula:

R^{h}-Q″′-E

wherein R^{h} is a hydrocarbon group, optionally containing one or more oxyalkylene groups or one or more reactive groups, such as hydroxy groups, amino groups, epoxy groups, and halogen atoms such as chlorine and bromine, Q′″ is a chemical bond or a divalent linking group as defined above for Q″, and E is an ethylenically unsaturated group as defined above. The hydrocarbon group is preferably selected from the group consisting of a linear, branched or cyclic alkyl group, an arylalkylene group, an alkylarylene group, and an aryl group. Preferred hydrocarbon groups contain from 4 to 30 carbon atoms.

Examples of non-fluorinated monomers from which the units M^{h} can be derived include general classes of ethylenic compounds capable of free-radical polymerization, such as allyl esters such as allyl acetate and allyl heptanoate; alkyl vinyl ethers or alkyl allyl ethers, such as cetyl vinyl ether, dodecyl vinyl ether, 2-chloroethyl vinyl ether, ethyl vinyl ether; anhydrides and esters of unsaturated acids such as acrylic acid, methacrylic acid, alpha-chloro acrylic acid, crotonic acid, maleic acid, fumaric acid, and itaconic acid; vinyl, allyl, methyl, butyl, isobutyl, hexyl, heptyl, 2-ethylhexyl, cyclohexyl, lauryl, stearyl, isobornyl or alkoxyethyl acrylates and methacrylates; alpha-beta unsaturated nitriles such as acrylonitrile, methacrylonitrile, 2-chloroacrylonitrile, 2-cyanoethyl acrylate, alkyl cyanoacrylates; allyl glycolate, acrylamide, methacrylamide, n-diisopropyl acrylamide, diacetoneacrylamide, N,N-diethylaminoethylmethacrylate, N-t-butylamino ethyl methacrylate; styrene and its derivatives such as vinyltoluene, alpha-methylstyrene, alpha-cyanomethyl styrene; lower olefinic hydrocarbons which can contain halogen such as ethylene, propylene, isobutene, 3-chloro-1-isobutene, butadiene, isoprene, chloro and dichlorobutadiene, 2,5-dimethyl-1,5-hexadiene, and allyl or vinyl halides such as vinyl and vinylidene chloride.

Preferred non-fluorinated monomers include hydrocarbon group containing monomers such as those selected from octadecyl methacrylate, lauryl methacrylate, butyl acrylate, N-methylol-acrylamide, isobutyl methacrylate, ethylhexyl acrylate and ethylhexyl methacrylate; and vinylchloride and vinylidene chloride.

The fluorinated oligomeric silane useful in the invention generally further includes units M^{a} that have a silyl group with hydrolyzable groups at the terminus of the units derived from one or more non-fluorinated monomers as defined above. Examples of units M^{a} include those that correspond to the general formula:

E-Z—SiY″₃

wherein E is an ethylenically unsaturated group as defined above, Y″ is as defined above, and Z is a chemical bond or a divalent linking group containing 1 to 20 carbon atoms and optionally containing oxygen, nitrogen, or sulfur-containing groups or a combination thereof. Z is preferably free of functional groups that substantially interfere with free-radical oligomerization (e.g., polymerizable olefinic double bonds, thiols, and other such functional groups known to those skilled in the art). Examples of suitable linking groups Z include straight chain, branched chain, or cyclic alkylene, arylene, arylalkylene, oxyalkylene, carbonyloxyalkylene, oxycarboxyalkylene, carboxyamidoalkylene, oxycarbonylaminoalkylene, ureylenealkylene, and combinations thereof.

For certain embodiments, Z is selected from the group consisting of alkylene, oxyalkylene, carbonyloxyalkylene, and the formula:

-Q³-T-C(O)NH-Q⁴—

wherein Q³ and Q⁴ are independently an organic divalent linking group selected from the group consisting of alkylene, arylene, oxyalkylene, carbonyloxyalkylene, oxycarboxyalkylene, carboxyamidoalkylene, oxycarbonylaminoalkylene, and ureylenealkylene; T is O or NR⁶ wherein R⁶ is hydrogen, C₁₋₄ alkyl, or aryl. For certain of these embodiments, Q⁴ is alkylene or arylene. Typical examples of such monomers include vinyltrichlorosilane, vinyltrimethoxysilane, vinyltriethoxysilane, and alkoxysilane functionalized acrylates or methacrylates, such as trimethoxysilylpropyl methacrylate and the like.

The fluorinated oligomeric silane is conveniently prepared through a free radical polymerization of a fluorinated monomer with optionally a non-fluorinated monomer and/or a monomer containing the silyl group in the presence of a chain transfer agent. A free radical initiator is generally used to initiate the polymerization or oligomerization reaction. Commonly known free-radical initiators can be used and examples thereof include azo compounds, such as azobisisobutyronitrile (AIBN), azo-2-cyanovaleric acid and the like, hydroperoxides such as cumene, t-butyl and t-amyl hydroperoxide, dialkyl peroxides such as di-t-butyl and dicumylperoxide, peroxyesters such as t-butylperbenzoate and di-t-butylperoxy phthalate, diacylperoxides such as benzoyl peroxide and lauroyl peroxide.

The oligomerization reaction can be carried out in any solvent suitable for organic free-radical reactions. The reactants can be present in the solvent at any suitable concentration (e.g., from about 5 percent to about 90 percent by weight based on the total weight of the reaction mixture). Examples of suitable solvents include aliphatic and alicyclic hydrocarbons (e.g., hexane, heptane, cyclohexane), aromatic solvents (e.g., benzene, toluene, xylene), ethers (e.g., diethylether, glyme, diglyme, diisopropyl ether), esters (e.g., ethyl acetate, butyl acetate), alcohols (e.g., ethanol, isopropyl alcohol), ketones (e.g., acetone, methylethyl ketone, methyl isobutyl ketone), sulfoxides (e.g., dimethyl sulfoxide), amides (e.g., N,N-dimethylformamide, N,N-dimethylacetamide), halogenated solvents such as methylchloroform, 1,1,2-trichloro-1,2,2-trifluoroethane, trichloroethylene, α,α,α-trifluorotoluene, and the like, and mixtures thereof.

The oligomerization reaction can be carried out at any temperature suitable for conducting an organic free-radical reaction. Particular temperature and solvents for use can be easily selected by those skilled in the art based on considerations such as the solubility of reagents, the temperature required for the use of a particular initiator, molecular weight desired and the like. While it is not practical to enumerate a particular temperature suitable for all initiators and all solvents, generally suitable temperatures are between about 30° C. and about 200° C., preferably between 50° C. and 100° C.

The fluorinated oligomeric silane is typically prepared in the presence of a chain transfer agent. Suitable chain transfer agents may include a hydroxy-, amino-, mercapto or halogen group. The chain transfer agent may include two or more of such hydroxy, amino-, mercapto or halogen groups. Typical chain transfer agents useful in the preparation of the fluorinated oligomeric silane include those selected from 2-mercaptoethanol, 3-mercapto-2-butanol, 3-mercapto-2-propanol, 3-mercapto-1-propanol, 3-mercapto-1,2-propanediol, 2-mercaptoethylamine, di(2-mercaptoethyl)sulfide, octylmercaptane, and dodecylmercaptane.

In a preferred embodiment, a chain transfer agent containing a silyl group having hydrolyzable groups is used in the oligomerization to produce the fluorinated oligomeric silane. Such chain transfer agents are of the following formula:

HS-Q⁵-SiY₃

wherein Q⁵ represents an organic divalent linking group such as for example a straight chain, branched chain or cyclic alkylene, arylene or arylalkylene; and each Y is independently a hydrolyzable group as defined above. Q⁵ is preferably C₁₋₂₀ alkylene.

Alternatively, a functionalized chain transfer agent or functionalized co-monomer can be used in the oligomerization. The functional group introduced by the functionalized chain transfer agent or functionalized co-monomer can then be reacted with a silyl group containing reagent subsequent to the oligomerization to introduce a silyl group having hydrolyzable groups.

A single chain transfer agent or a mixture of different chain transfer agents may be used. For certain embodiments, 2-mercaptoethanol, octylmercaptane, and 3-mercaptopropyltrimethoxysilane are preferred chain transfer agents. A chain transfer agent is typically present in an amount sufficient to control the number of polymerized monomer units in the oligomer and to obtain the desired molecular weight of the oligomeric fluorochemical silane.

The fluorinated oligomeric silane can be prepared by oligomerizing a fluorinated monomer and optional non-fluorinated monomer with a monomer E-Z—SiY″₃, wherein at least one Y″ represents a hydrolysable group, in the presence of a chain transfer agent which may optionally also contain a silyl group such as, for example, HS-Q⁵-SiY₃.

As a variation to the above method the oligomerization may be carried out without the use of the silyl group containing monomer but with a chain transfer agent containing the silyl group.

In another embodiment, the at least partially fluorinated composition comprising at least one silane group is a swallow-tail silane of the Formula IV:

R⁴_{f}S(O)₂—N(R⁷)—(CₙH₂ₙ)—CH(Z¹)—(CₘH₂ₘ)—N(R⁸)—S(O)₂R⁴_{f} IV

wherein each R⁴_{f} is independently CₚF₂ₚ₊₁, wherein p is 1 to 8; R⁷ is C₁₋₄ alkyl or aryl; m and n are both integers from 1 to 20; Z¹ is hydrogen or a group of the formula —(C_{m′}H_{2m′})—X-Q⁵-Si(Y)₃ wherein m′ is 0 to 4, X¹ is O, S, or NH, Q⁵ is —C(O)NH—(CH₂)_{n′}- or —(CH₂)_{n′}—, n′ is an integer of 1 to 20, and Y is a hydrolysable group; and R⁸ is R⁷ or a group of the formula —(CH₂)ₙ—Si(Y)₃, with the proviso that when Z¹ is hydrogen, then R⁸ is a group of the formula —(CH₂)ₙ—Si(Y)₃.

Each R⁴_{f} may be the same or different, and each contains 1-8 carbon atoms, preferably 2-5 carbon atoms, more preferably 4 carbon atoms.

For certain embodiments, including any one of the above embodiments of Formula IV, m is an integer from 1 to 6, and n is an integer from 1 to 6.

For certain embodiments, including any one of the above embodiments of Formula IV, R⁷ is C₁₋₄ alkyl. For certain of these embodiments, C₁₋₄ alkyl is methyl or ethyl.

For certain embodiments, including any one of the above embodiments of Formula IV, R⁸ is C₁₋₄ alkyl. For certain of these embodiments, C₁₋₄ alkyl is methyl or ethyl.

For certain embodiments, including any one of the above embodiments of Formula IV except where R⁷ is C₁₋₄ alkyl, R⁷ is aryl.

For certain embodiments, including any one of the above embodiments of Formula IV except where R⁸ is C₁₋₄ alkyl, R⁸ is aryl.

For certain embodiments where R⁷ and/or R⁸ is aryl, aryl is phenyl which is unsubstituted or substituted by one or up to five substituents independently selected from the group consisting of C₁₋₄ alkyl, C₁₋₄ alkoxy, halogen (e.g. fluoro, chloro, bromo, and/or iodo groups), hydroxy, amino, and nitro. When substituents are present, halogen and C₁₋₄ alkyl substituents are preferred.

For certain embodiments, including any one of the above embodiments of Formula IV, n′ is an integer from 1 to 10, and in one embodiment n′ is 3.

For certain embodiments, including any one of the above embodiments of Formula IV, Y is defined as in any one of the above definitions of Y. For certain of these embodiments, Y is —OC₁₋₄ alkyl, —OC(O)CH₃, or Cl.

For certain embodiments, swallow-tail silanes of the Formula IV include, but are not limited to [C₄F₉S(O)₂N(CH₃)CH₂]₂CHOCH₂CH₂CH₂Si(OCH₃)₃, [C₄F₉S(O)₂N(CH₃)CH₂]₂CHOC(O)NHCH₂CH₂CH₂Si(OCH₃)₃, and C₄F₉S(O)₂N(CH₃)CH₂CH₂CH₂N(S(O)₂C₄F₉)CH₂CH₂CH₂Si(OCH₃)₃.

The swallow-tail silane of the Formula IV may be prepared by known methods. For example, [C₄F₉S(O)₂N(CH₃)CH₂]₂CHOH may be made by reacting two moles of C₄F₉S(O)₂NHCH₃ with either 1,3-dichloro-2-propanol or epichlorohydrin in the presence of a base. [C₄F₉S(O)₂N(CH₃)CH₂]₂CHOCH₂CH₂CH₂Si(OCH₃)₃ can be made from [C₄F₉S(O)₂N(CH₃)CH₂]₂CHOH by alkylation with ClCH₂CH₂CH₂Si(OCH₃)₃ or by alkylation with allyl chloride, followed by hydrosilation with HSiCl₃ and methanolysis. Reaction of [C₄F₉S(O)₂N(CH₃)CH₂]₂CHOH with OCNCH₂CH₂CH₂Si(OCH₃)₃ yields [C₄F₉S(O)₂N(CH₃)CH₂]₂CHOC(O)NHCH₂CH₂CH₂Si(OCH₃)₃.

For certain embodiments, including any one of the above embodiments, the at least partially fluorinated composition comprising at least one silane group further includes an organic solvent.

For certain embodiments, including any one of the above embodiments wherein the at least partially fluorinated composition comprising at least one silane group is a polyfluoropolyether silane, the polyfluoropolyether silane is applied as a composition comprising the polyfluoropolyether silane and an organic solvent.

The organic solvent or blend of organic solvents used must be capable of dissolving at least about 0.01 percent by weight of one or more silanes of the Formulas I through IV. For certain embodiments, it is desirable that the solvent or mixture of solvents have a solubility for water of at least about 0.1 percent by weight, and for certain of these embodiments, a solubility for acid of at least about 0.01 percent by weight.

Suitable organic solvents, or mixtures of solvents can be selected from aliphatic alcohols, such as methanol, ethanol, and isopropanol; ketones such as acetone and methyl ethyl ketone; esters such as ethyl acetate and methyl formate; ethers such as diethyl ether, diisopropyl ether, methyl t-butyl ether and dipropyleneglycol monomethylether (DPM); hydrocarbons solvents such as alkanes, for example, heptane, decane, and paraffinic solvents; fluorinated hydrocarbons such as perfluorohexane and perfluorooctane; partially fluorinated hydrocarbons, such as pentafluorobutane; hydrofluoroethers such as methyl perfluorobutyl ether and ethyl perfluorobutyl ether.

For certain embodiments, including any one of the above embodiments, the organic solvent is a fluorinated solvent, which includes fluorinated hydrocarbons, partially fluorinated hydrocarbons, and hydrofluoroethers. For certain of these embodiments, the fluorinated solvent is a hydrofluoroether. For certain of these embodiments, the hydrofluoroether is methyl perfluorobutyl ether.

For certain embodiments, including any one of the above embodiments except where the organic solvent is a fluorinated solvent, the organic solvent is a lower alcohol. For certain of these embodiments, the lower alcohol is selected from the group consisting of methanol, ethanol, isopropanol, and mixtures thereof. For certain of these embodiments, the lower alcohol is ethanol.

For certain embodiments, including any one of the above embodiments where the organic solvent is a lower alcohol, the at least partially fluorinated composition comprising at least one silane group further comprises an acid. For certain of these embodiments, the acid is selected from the group consisting of acetic acid, citric acid, formic acid, triflic acid, perfluorobutyric acid, sulfuric acid, and hydrochloric acid. For certain of these embodiments, the acid is hydrochloric acid.

The at least partially fluorinated composition comprising at least one silane group, including any one of the above embodiments, can be applied to at least a portion of the surface of the layer comprising the silicon, oxygen, and hydrogen using a variety of coating methods. Such methods include but are not limited to spraying, dipping, rolling, brushing, spreading, flow coating, and vapor deposition.

For certain embodiments, including any one of the above embodiments, the at least partially fluorinated composition comprising at least one silane group, in any one of its above described embodiments, is applied by dipping at least a portion of the substrate upon which the layer comprising the silicon, oxygen, and hydrogen has been formed in the at least partially fluorinated composition comprising at least one silane group.

Alternatively, for certain embodiments, including any one of the above embodiments, the at least partially fluorinated composition comprising at least one silane group, in any one of its above described embodiments, is applied by spraying at least a portion of the substrate upon which the layer comprising the silicon, oxygen, and hydrogen has been formed with the at least partially fluorinated composition comprising at least one silane group.

For certain embodiments, including any one of the above embodiments except where the at least partially fluorinated composition comprising at least one silane group, is applied by other means, the at least partially fluorinated composition comprising at least one silane group, in any one of its above described embodiments, is applied by chemical vapor deposition to at least a portion of the substrate upon which the layer comprising the silicon, oxygen, and hydrogen has been formed. For certain of these embodiments, the at least partially fluorinated composition comprising at least one silane group is a polyfluoropolyether silane.

The conditions under which the at least partially fluorinated composition comprising at least one silane group, for example, the polyfluoropolyether silane is vaporized during chemical vapor deposition may vary according to the structure and molecular weight of the polyfluoropolyether silane. For certain embodiments, the vaporizing may take place at pressures less than about 1.3 Pa (about 0.01 torr), at pressures less than about 0.013 Pa (about 10⁻⁴ torr) or even about 0.0013 Pa to about 0.00013 Pa (about 10⁻⁵ torr to about 10⁻⁶ torr). For certain of these embodiments, the vaporizing may take place at temperatures of at least about 80° C., at least about 100° C., at least about 200° C., or at least about 300° C. Vaporizing may include imparting energy by, for example conductive heating, convective heating, microwave radiation heating, and the like.

The chemical vapor deposition method may reduce opportunities for contamination of the surface of the substrate through additional handling and exposure to the environment, leading to correspondingly lower yield losses. Furthermore, as the layer comprising silicon, oxygen, and hydrogen is formed by plasma deposition, it can be more efficient to apply the at least partially fluorinated composition comprising at least one silane group, for example, the polyfluoropolyether silanes in the same chamber or a connected vacuum chamber. Additionally, the polyfluoropolyether silane coatings applied by chemical vapor deposition may not need acid conditions and/or additional heating for curing. Useful vacuum chambers and equipment are known in the art. Examples include the Plasmatherm Model 3032 (available from Plasmatherm, Kresson, N.J.) and the 900 DLS (available from Satis Vacuum of America, Grove Port, Ohio).

In one embodiment, applying the polyfluoropolyether silane by chemical vapor deposition comprises placing the polyfluoropolyether silane and the substrate, having the layer comprising silicon, oxygen, and hydrogen on at least a portion of the surface of the substrate, into a chamber, decreasing the pressure in the chamber, and heating the polyfluoropolyether silane. The polyfluoropolyether silane is typically maintained in a crucible, but in some embodiments, the silane is imbibed in a porous matrix, such as a ceramic pellet, and the pellet heated in the vacuum chamber.

The at least partially fluorinated composition comprising at least one silane group, including any one of the above embodiments of Formulas I, II, III, and/or IV, undergoes reaction with the layer comprising the silicon, oxygen, and hydrogen on the substrate surface, for example, with —SiOH groups, to form a durable coating, through the formation of covalent bonds, including bonds in Si—O—Si groups. For the preparation of a durable coating, sufficient water should be present to cause hydrolysis of the hydrolyzable groups described above so that condensation to form Si—O—Si groups takes place, and thereby curing takes place. The water can be present either in the coating composition or adsorbed to the substrate surface, for example. Typically, sufficient water is present for the preparation of a durable coating if the coating method is carried out at room temperature in an atmosphere containing water, for example, an atmosphere having a relative humidity of about 30% to about 50%.

A substrate to be coated can typically be contacted with the coating composition at room temperature (typically, about 15° C. to about 30° C., or about 20° C. to about 25° C.). Alternatively, the coating composition can be applied to substrates which are preheated at a temperature of, for example, between 60° C. and 150° C. Following application of the at least partially fluorinated composition comprising at least one silane group, the treated substrate can be dried and the resulting coating cured at ambient temperature, e.g., about 15° C. to about 30° C., or elevated temperature (e.g., at about 40° C. to about 300° C.) and for a time sufficient for the curing to take place.

For certain embodiments, including any one of the above embodiments, the method of forming an easy-to-clean metal or metallized substrate further comprises the step of subjecting the substrate to an elevated temperature after applying the at least partially fluorinated composition comprising at least one silane group.

For certain embodiments, including any one of the above embodiments where the at least partially fluorinated composition comprising at least one silane group is a polyfluoropolyether silane, the method of forming an easy-to-clean metal or metallized substrate further comprises the step of subjecting the substrate to an elevated temperature after applying the polyfluoropolyether silane.

For certain embodiments, including any one of the above embodiments where the at least partially fluorinated composition comprising at least one silane group further comprises an acid, except where an elevated temperature is used, the method of forming an easy-to-clean metal or metallized substrate further comprises the step of allowing the substrate to dry at a temperature of about 15° C. to about 30° C. after applying the composition.

In another aspect, there is provided an easy-to-clean coated article comprising:

at least one of a metal substrate or a metallized substrate;

a plasma deposited layer disposed on the substrate, wherein the plasma deposited layer comprises at least about 10 atomic percent silicon, at least about 10 atomic percent oxygen, and at least about 5 atomic percent hydrogen; wherein all atomic percent values are based on the total atomic weight of the plasma deposited layer; and

a coating bonded to the plasma deposited layer;

wherein the coating comprises an at least partially fluorinated composition comprising at least one silane group which shares at least one covalent bond with the plasma deposited layer.

In one preferred embodiment, there is provided an easy-to-clean coated article comprising:

at least one of a metal substrate or a metallized substrate;

a plasma deposited layer disposed on the substrate, wherein the plasma deposited layer comprises at least about 10 atomic percent silicon, at least about 10 atomic percent oxygen, and at least about 5 atomic percent hydrogen; wherein all atomic percent values are based on the total atomic weight of the plasma deposited layer; and

a polyfluoropolyether-containing coating bonded to the plasma deposited layer;

wherein the polyfluoropolyether-containing coating comprises polyfluoropolyether silane groups of the following Formula Ib:

R_{f}[Q′-C(R)₂—Si(O—)₃₋ₓ(R^{1a})ₓ]_{z} Ib

which shares at least one covalent bond with the plasma deposited layer; and

wherein:
R_{f} is a monovalent or multivalent polyfluoropolyether segment;
Q′ is an organic divalent linking group;
each R is independently hydrogen or a C₁₋₄ alkyl group;
R^{1a} is a C₁₋₈ alkyl or phenyl group;
x is 0 or 1 or 2; and
z is 1, 2, 3, or 4.
   The at least on covalent bond shared with the plasma deposited layer is a bond to an oxygen atom in Si(O—)₃₋ₓ.

For certain embodiments of the easy-to-clean coated article, the plasma deposited layer comprises at least about 20 atomic percent silicon, based on the total atomic weight of the plasma deposited layer. The atomic percent of silicon, as well as other elements such as oxygen and carbon, can be determined by a well established quantitative surface analytical technique such as Electron Spectroscopy for Chemical Analysis (ESCA) or Auger Electron Spectroscopy (AES). The atomic percentage as determined by ESCA and AES techniques is based on a hydrogen-free basis. Hydrogen content in the film may be determined by techniques such as Infra-Red Spectroscopy (IR) or quantitatively by combustion analysis or Rutherford Backscattering Spectroscopy (RBS).

For certain embodiments, including any one of the above embodiments of the easy-to-clean coated article, the plasma deposited layer further comprises at least about 15 atomic percent oxygen, based on the total atomic weight of the plasma deposited layer.

For certain embodiments, including any one of the above embodiments of the easy-to-clean coated article, the plasma deposited layer further comprises carbon and/or nitrogen such that the total atomic content of the carbon and/or nitrogen is at least 5 atomic percent, based on the total atomic weight of the plasma deposited layer. For certain of these embodiments, the plasma deposited layer further comprises carbon such that the total atomic content of the carbon is at least 5 atomic percent, based on the total atomic weight of the plasma deposited layer.

For certain embodiments, including any one of the above embodiments of the easy-to-clean coated article, the thickness of the plasma deposited layer is at least about 0.5 nanometer and not more than about 100 nanometers. For certain of these embodiments, the thickness of the plasma deposited layer is at least about 1 nanometer and not more than about 10 nanometers.

For certain embodiments, the plasma deposited layer imparts at least one of a color hue or an increased intensity of a color hue.

For certain embodiments, including any one of the above embodiments of the easy-to-clean coated article, the monovalent or multivalent polyfluoropolyether segment, R_{f}, is defined according to any one of the embodiments of R_{f} described in the above method.

For certain embodiments, including any one of the above embodiments of the easy-to-clean coated article, the polyfluoropolyether segment, R_{f}, includes perfluorinated repeating units selected from the group consisting of —(CₙF₂ₙO)—, —(CF(Z)O)—, —(CF(Z)CₙF₂ₙO)—, —(CₙF₂ₙCF(Z)O)—, —(CF₂CF(Z)O)—, and combinations thereof; and wherein Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted; and n is an integer from 1 to 12.

For certain embodiments, including any one of the above embodiments of the easy-to-clean coated article, R_{f} is selected from the group consisting of —CF₂O(CF₂O)ₘ(C₂F₄O)ₚCF₂—, —CF(CF₃)—(OCF₂CF(CF₃))ₚO—R_{f}—O(CF(CF₃)CF₂O)ₚCF(CF₃)—, —CF₂O(C₂F₄O)ₚCF₂—, and —(CF₂)₃O(C₄F₈O)ₚ(CF₂)₃—, and wherein R_{f}′ is a divalent, perfluoroalkylene group containing at least one carbon atom and optionally interrupted in chain by O or N, m is 1 to 50, and p is 3 to 40. For certain of these embodiments, R_{f} is —CF₂O(CF₂O)ₘ(C₂F₄O)ₚCF₂—, and Q-C(R)₂—Si(Y)₃₋ₓ(R¹)ₓ is C(O)NH(CH₂)₃Si(OR)₃, wherein R¹ is methyl or ethyl.

As indicated above, substrates used in the method and easy-to-clean article of the invention are comprised of a metal and/or metal alloy, which is solid at room temperature. For certain embodiments, the substrate is preferably comprised of a hard surface. A hard surface is capable of retaining its shape and structure without deforming appreciably when wiped.

For certain embodiments, including any one of the above embodiments, the substrate comprises at least one of chromium or a chromium alloy. For certain of these embodiments, a major surface of the substrate further comprises a chromium oxide.

For certain embodiments, including any one of the above embodiments of the easy-to-clean coated article, the thickness of the polyfluoropolyether-containing coating is at least about 20 nanometers, preferably at least about 30 nanometers, and most preferably at least about 50 nanometers. For certain of these embodiments, the thickness is not more than about 200 nanometer, preferably not more than about 150 nanometers, and most preferably not more than about 100 nanometers.

Objects and advantages of this invention are further illustrated by the following examples, but the particular materials and amounts thereof recited in these examples, as well as other conditions and details, should not be construed to unduly limit this invention.

### EXAMPLES

### Preparation of (CH₃O)₃Si(CH₂)₃NHCOCF₂(OCF₂CF₂)₉₋₁₀(OCF₂)₉₋₁₀OCF₂CONH(CH₂)₃Si(OCH₃)₃

CH₃OC(O)CF₂(OCF₂CF₂)₉₋₁₀(OCF₂)₉₋₁₀OCF₂C(O)OCH₃ (a perfluoropolyether diester obtained from Solvay Solexis, Houston, Tex., available under the trade designation “FOMBLIN ZDEAL”) (50 grams (g)) was added to an oven-dried 100-mL round bottom flask under a nitrogen atmosphere and stirred rapidly at room temperature using a magnetic stirrer. 3-Aminopropyltrimethoxysilane (9.1 g) (obtained from GE Silicones, Wilton, Conn., available under the trade designation “SILQUEST A-1110”) was added to the flask in one portion. Initially the mixture was two-phase, and as the reagents mixed the mixture became cloudy. A reaction exotherm to a temperature of 30° C. was observed, and then the reaction gradually cooled to room temperature and became a slightly hazy light yellow liquid. The reaction was monitored by gas chromatography (GC) to observe excess 3-aminopropyltrimethoxysilane and fourier transform infrared spectroscopy (FTIR) to observe unreacted ester functional groups and was found to be complete within 30 minutes after the addition of 3-aminopropyltrimethoxysilane.

The reaction product was stirred rapidly, and the pressure in the flask was reduced to 1 mmHg (133 Pa) gradually to minimize bumping. Methanol was distilled from the flask over a period of two hours, and 57.5 g of (CH₃O)₃Si(CH₂)₃NHCOCF₂(OCF₂CF₂)₉₋₁₀(OCF₂)₉₋₁₀OCF₂CONH(CH₂)₃Si(OCH₃)₃ was recovered from the flask.

### Plasmatherm Batch Reactor

Examples 1-8 were treated in batch plasma system Plasmatherm Model 3032, available from Plasmatherm, Kresson, N.J., which was configured for reactive ion etching with a 26-inch lower powered electrode and central gas pumping. The chamber was connected to a roots style blower (Edwards Model EH1200, Boc Edwards, West Sussex, United Kingdom) backed by a dry mechanical pump (Edwards Model iQDP80, Boc Edwards). Plasma was powered by a 5 kW, 13.56 MHz solid-state generator (RF Plasma Products Model RF50S0, available from MKS Power Generators and Subsystems, Wilmington, Mass.) and a radio frequency impedance matching network (Plasmatherm Model AMN-30, available from Plasmatherm). The system had a nominal base pressure of 5 mTorr (0.67 Pa). The flow rates of gases were controlled by flow controllers available from MKS Power Generators and Subsystems. Substrates for deposition were placed on the lower powered electrode.

The substrates used in Examples 1-5 and 8, Comparative Example 1, and control experiments (i.e., tests on substrates with no treatment) were obtained from Ideal Standard, Wittlich, Germany. The substrates for Examples 1-3, 5, and 8, Comparative Example 1, and the control experiments were metal fittings with a layer of electroplated chromium on the surface. The substrate for Example 4 was a plastic plate with a layer of electroplated chromium on the surface. The substrate for Example 7 was an aluminum panel, available from ACT Laboratories, Inc., Hillsdale, Mich.

### Examples 1 and 2

### Plasma Treatment Method

Step 1. A small faucet fitting (Example 1) and a large faucet fitting (Example 2) were first treated in an oxygen plasma by flowing oxygen gas (99.99%, UHP Grade, available from Scott Specialty Gases, Plumsteadville, Pa.), at 500 standard cubic centimeters per minute (sccm) flow rate and maintaining the pressure at 52 millitorr (mtorr) (6.9 Pascals (Pa)) and plasma power of 1000 watts. The oxygen priming step was carried out for 20 seconds.

Step 2. Following the oxygen plasma priming, tetramethylsilane (99.9%, NMR Grade, available from Sigma-Aldrich Chemicals, St. Louis, Mo.) was introduced. Tetramethylsilane vapor was introduced into the chamber at a flow rate of 150 sccm while the oxygen flow was maintained at 500 sccm. The pressure was held at 64 mtorr (8.5 Pa), and plasma power was held at 1000 watts. The treatment time was 10 seconds.

Step 3. The tetramethylsilane gas was then shut off and the oxygen gas continued to run at a flow of 500 sccm. The pressure was maintained at 150 mtorr (20 Pa), and plasma power delivered at 300 watts. This final step of post-deposition oxygen plasma treatment lasted 60 seconds. After the three plasma treatment steps were completed, the chamber was vented to atmosphere and the fittings were wrapped in aluminum foil.

### Silane Treatment

A solution (3 liters (L)) of 0.1% (CH₃O)₃Si(CH₂)₃NHCOCF₂(OCF₂CF₂)₉₋₁₀(OCF₂)₉₋₁₀OCF₂CONH(CH₂)₃Si(OCH₃)₃ in HFE-7100 fluid (available from 3M Company, St. Paul, Minn. under the trade designation “NOVEC HFE-7100”) was placed in a 4-L beaker at room temperature. The beaker was placed in a dip coater. Each fitting, which had been plasma-treated according to the method described above, was fixed vertically above the solution and introduced into the solution at a controlled rate. Once the fitting was submerged entirely into the solution, it was held in place for five seconds. The fitting was withdrawn from the solution at 15 millimeters (mm) per second and then placed in an aluminum pan. The pan was then placed in an oven at 100° C. for 30 minutes. The fitting was then allowed to stand at least 24 hours before contact angle measurement.

Contact angles versus water and hexadecane were measured on the fittings of Examples 1 and 2 using a KRUSS G120/G140 MKI goniometer (Kruss USA, Charlotte, N.C.). Larger values of contact angles indicate better repellency. The mean values of 3 measurements and are reported in degrees in Table 1 (below).

TABLE 1

| | Contact angles (°) | | | Contact angles (°) | | |
|---|---|---|---|---|---|---|
| | versus water | | | versus hexadecane | | |
| Treatment | advancing | static | receding | advancing | static | receding |
| Example 1 | 120.6 | 110.9 | 88.2 | 72.55 | 69.9 | 56.25 |
| Example 2 | 122.33 | 112.83 | 96.26 | 71.7 | 69.35 | 60.4 |

### Example 3

A nearly flat, round metal disc having a layer of electroplated chromium was treated according to the plasma treatment method of Examples 1 and 2 except that in Step 1, the pressure was maintained at 45 mtorr (6.0 Pa), and in Step 2, the pressure was held at 50 mTorr (6.7 Pa). Prior to the plasma treatment, the chamber was pumped down to a base pressure of 10 mtorr (1.3 Pa). The disc was then dip coated according to the silane treatment method of Examples 1 and 2 except the samples were heated in a forced-air oven at 120° C. for 20 minutes after the coating step.

The method of Example 3 was repeated, using treatment times in Step 2 of 2 seconds, 5 seconds, and 20 seconds. After a 20-second treatment, the color of the surface of the fitting turned to a slightly brown color. Each treatment time resulted in a fitting with improved cleanability.

### Comparative Example 1

A nearly flat, round metal disc having a layer of electroplated chromium was dip coated according to the silane treatment method of Examples 1 and 2 except the sample was heated in a forced-air oven at 120° C. for 20 minutes after the coating step. No plasma treatment step was carried out.

Static contact angles were measured versus water and hexadecane on the discs of Example 3 and Comparative Example (CE) 1 and an untreated disc using an Olympus model TGHM goniometer (available from Olympus Corporation of America, Pompano Beach, Fla.). An abrasion test was carried out by applying all-purpose cleaner (available from S C Johnson, Racine, Wis., under the trade designation “MR MUSCLE”) and wiping with a wipe (available from 3M Company, St. Paul, Minn. under the trade designation “3M HIGH PERFORMANCE WIPE”) 5000 times. Static contact angles were measured again after the abrasion test. For contact angles measurements, the mean values of 3 measurements and are reported in degrees in Table 2 (below).

TABLE 2

| | |
|---|---|
| Contact Angle (°) | Contact Angle (°) |
| Before abrasion test | After abrasion test |

| Treatment | water | hexadecane | water | hexadecane |
|---|---|---|---|---|
| Example 3 | 108 | 68 | 95 | 58 |
| CE 1 | 96 | 62 | 55 | 35 |
| None | 42 | <20 | 40 | <20 |

The cleanability of the fittings of Example 3 and CE 1 and an untreated disc was carried out by applying mineral water (available from Tonissteiner, Germany). The water was sprayed at 0.5 bar (5×10⁴ Pa) at room temperature until the substrate was completely covered. The substrate was placed in an oven for two hours at 70° C., removed, and allowed to cool. Limestone deposits were present on the substrates, which were then cleaned with a dry paper wipe. The cleaning results were evaluated visually and rated on a scale of 0 (impossible to remove the deposits) to 10 (no visual marks left after 3 wipes). The substrates were subjected to the test procedure up to five times. The results are shown in Table 3 (below).

TABLE 3

| Treatment | Cleanability Rating (0-10) |
|---|---|
| Example 3 | 9 after 5 test cycles |
| CE 1 | 1 after 2 test cycles |
| None | 0 after 1 test cycle |

### Examples 4-8

The plasma treatment method of Examples 1 and 2 was applied to the substrates shown in Table 4 (below).

TABLE 4

| | | Static | | Advancing | | Receding | |
|---|---|---|---|---|---|---|---|
| | | Contact | | Contact | | Contact | |
| | | Angle (°) | | Angle (°) | | Angle (°) | |
| | | | hexa- | | hexa- | | hexa- |
| Example | Substrate | water | decane | water | decane | water | decane |
| 4 | Chromed | 106.9 | 68.3 | 116.7 | 70.0 | 84.1 | 67.2 |
| | Plastic | | | | | | |
| | Plate | | | | | | |
| 5 | Chromed | 105.9 | 67.7 | 115.0 | 71.7 | 72.4 | 66.0 |
| | Metal Plate | | | | | | |
| 6 | Stainless | 103.3 | 67.6 | 111.5 | 69.2 | 75.5 | 65.1 |
| | Steel Plate | | | | | | |
| 7 | Aluminum | 105.5 | 67.8 | 112.5 | 70.9 | 65.5 | 56.3 |
| | Plate | | | | | | |
| 8 | Chromed | 106.5 | 68.5 | 120.8 | 77.0 | 40.3 | 44.5 |
| | Metal | | | | | | |
| | Handle | | | | | | |
| control | Untreated | 53.2 | low^{a} | 49.9 | low^{a} | 14.2 | low^{a} |
| | Chromed | | | | | | |
| | Metal Plate | | | | | | |

^{a}too low to measure

After the plasma treatment, the substrates were wrapped in a knitted polyester wipe (available from VWR International, West Chester, Pa.).

### Chemical Vapor Deposition (CVD) of Silanes

The substrates were placed in a vapor deposition chamber, and (CH₃O)₃Si(CH₂)₃NHCOCF₂(OCF₂CF₂)₉₋₁₀(OCF₂)₉₋₁₀OCF₂CONH(CH₂)₃Si(OCH₃)₃ was placed on a black graphite strip inside the chamber using a syringe. Vacuum was applied, and when the pressure in the chamber reached 4×10 ⁻⁶ torr (5.3×10⁻⁴ Pa), heat was applied to the black graphite strip using a variac. (CH₃O)₃Si(CH₂)₃NHCOCF₂(OCF₂CF₂)₉₋₁₀(OCF₂)₉₋₁₀OCF₂CONH(CH₂)₃Si(OCH₃)₃ was vaporized at 450° C.-500° C. to form a thin coating on the metal surface.

The coated substrates were allowed to stand at ambient conditions for 24 hours before contact angle measurements were taken. Contact Angles were measured for Examples 4-8 and an untreated chromed metal plate using the method described above for Examples 1 and 2. The results are shown in Table 4 (above).

Coating compositions are provided that include a hexafluoropropylene oxide derived silane polymer having a number average molecular weight of about 5500 grams per mole or greater. The coating compositions can be applied to a siliceous substrate to form an article. The polymeric hexafluoropropylene oxide derived silane has a silyl group that can react with a surface of the siliceous substrate forming a —Si—O—Si— bond. The resulting article can be used to provide a surface with abrasion resistance, easy to clean characteristics, good tactile response (i.e., a finger can easily slide over the surface), or a combination thereof. A surprising relationship has been found between the molecular weight of the coating composition and abrasion resistance. Additionally, it was surprisingly found that, by modification of the molecular weight of the coating composition, the coefficient of friction can be modified and improved. As the molecular weight of the coating composition increases, the abrasion resistance increases. With increasing molecular weight of the coating, the coefficient of friction decreases, resulting in an improved coefficient of friction.

The recitation of any numerical range by endpoints is meant to include the endpoints of the range, all numbers within the range, and any narrower range within the stated range.

The term “a”, “an”, and “the” are used interchangeably with “at least one” to mean one or more of the elements being described.

The term “and/or” means either or both. For example, the expression “A and/or B” means A, B, or a combination of A and B.

The term “fluorinated” refers to a group or compound that contains at least one fluorine atom attached to a carbon atom.

The term “perfluorinated” refers to a group or compound having all C—H bonds replaced with C—F bonds. Examples include perfluoropolyether groups or compounds, perfluoroether groups or compounds, and perfluoroalkane groups or compounds. Perfluorinated groups or compounds are a subset of fluorinated groups or compounds.

The term “ether” refers to a group or compound having an oxy group between two carbon atoms. Ether groups are often divalent groups such as —CH₂—O—CH₂— or —CF₂—O—CF₂—.

The term “polyether” refers to a group or compound having multiple ether groups.

The term “thioether” refers to a group or compound having a thio group between two carbon atoms. Thioether groups are the divalent group —CH₂—S—CH₂—.

The term “hexafluoropropylene oxide derived silane” refers to a polymer of hexafluoropropylene oxide which has been functionalized with a silane functional group.

The coating compositions include a hexafluoropropylene oxide derived silane polymer having a number average molecular weight of about 5500 grams/mole or greater, particularly about 9000 grams/mole or greater and more particularly about 20000 grams/mole or greater. At number average molecular weights of less than 5500 grams/mol, the polymeric coating does not display effective abrasion resistance and has a higher coefficient of friction. The number average molecular weight of the hexafluoropropylene oxide derived silane polymer may be a single molecular weight or a combination of molecular weights. For example, the hexafluoropropylene oxide derived silane polymer may be a blend of one or more higher molecular weight materials provided that the number average molecular weight of the blended hexafluoropropylene oxide derived silane polymer is about 5500 grams/mole or greater. Examples of suitable polymeric hexafluoropropylene oxide derived silanes include, but are not limited to, hexafluoropropylene oxide derived thioether silanes and hexafluoropropylene oxide derived ether silanes having a molecular weight of about 5500 or greater.

Water and hexadecane contact angles provide an indication of the durability of the polymeric hexafluoropropylene oxide derived silane coatings. As the polymeric coating is abraded and the underlying substrate is exposed, both the hexadecane and water contact angles decrease from their values measured on the initial coated substrate. The contact angle of the polymeric hexafluoropropylene oxide derived silane coating should preferably remain substantially the same through a number of abrasion cycles. In one embodiment, after 10000 abrasion cycles, the water contact angle of the polymeric hexafluoropropylene oxide derived silane coating decreased from its initial contact angle by less than about 27%, particularly less than about 25%, and more particularly less than about 22%.

In one embodiment, after 10000 abrasion cycles, the hexadecane contact angle of the polymeric hexafluoropropylene oxide derived silane coating decreased from its initial contact angle by less than about 8%, particularly less than about 6%, and more particularly less than about 4%.

In one embodiment, the polymeric hexafluoropropylene oxide derived silane coating applied onto a piece of float glass has a coefficient of friction constant of less than about 0.35 particularly less than about 0.32 and more particularly less than about 0.30.

Very thin coatings of one nanometer or less do not have sufficient abrasion durability and conversely coatings thicker than about 1000 nanometers have very poor abrasion durability. In one embodiment, the polymeric hexafluoropropylene oxide derived silane coating has a thickness of between about 2 and about 15 nanometers particularly between about 2 and about 10 nanometers and more particularly between about 4 and about 10 nanometers.

The polymeric hexafluoropropylene oxide derived silane coating includes a fluorinated silane of Formula (I).

F(CF(CF₃)CF₂O)ₙCF(CF₃)—CH₂O—CH₂CH₂CH₂-L-Si(R¹)₃₋ₓ(R²)ₓ (I)

In Formula (I), L is a single bond or —S—CH₂CH₂CH₂—. Group R¹ is hydroxy or a hydrolyzable group. Group R² is a non-hydrolyzable group. The variable x is equal to 0, 1, or 2. The variable n is an integer in a range of about 4 to about 150, in a range of about 5 to about 150, in a range of about 10 to about 150, in a range of about 10 to about 120, in a range of about 10 to about 100, in a range of about 10 to about 60, in a range of about 10 to about 40, in a range of about 20 to about 150, in a range of about 40 to about 150, in a range of about 50 to about 150, or in a range of about 60 to about 150.

In some fluorinated silanes, the group L is a single bond and the fluorinated silane of Formula (I) is of Formula (IA).

F(CF(CF₃)CF₂O)ₙCF(CF₃)—CH₂O—CH₂CH₂CH₂—Si(R¹)₃₋ₓ(R²)ₓ (IA)

In other fluorinated silanes, the group L is —S—CH₂CH₂CH₂— and the fluorinated silane of Formula (I) is of Formula (IB).

F(CF(CF₃)CF₂O)ₙCF(CF₃)—CH₂O—CH₂CH₂CH₂—S—CH₂CH₂CH₂—Si(R¹)₃₋ₓ(R²)ₓ (IB)

The fluorinated silane has a perfluoropolyether group of formula F(CF(CF₃)CF₂O)ₙCF(CF₃)—. The perfluoropolyether group has multiple branched hexafluoropropylene oxide —(CF(CF₃)CF₂O)— groups. The number average molecular weight of the perfluoropolyether group of the fluorinated silane is at least about 5500 grams/mole, at least about 8000 grams/mole, at least about 12000 grams/mole, or at least about 20000 grams/mole. In some embodiments, higher number average molecular weights can further enhance durability. Generally, for ease of use and application, the number average molecular weight of the perfluoropolyether group is often up to about 20,000 grams/mole, up to about 12,000 grams/mole, up to about 10,000 grams/mole, up to about 7,500 grams/mole, up to about 6000 grams/mole or up to about 5500 grams/mole. In some embodiments, the number average molecular weight of the perfluoropolyether group is in a range of about 5500 to about 20,000 grams/mole, in a range of about 5500 to about 15,000 grams/mole, in a range of about 5500 to about 10000 grams/mole.

The fluorinated silane of Formula (I) has a silyl group —Si(R¹)₃₋ₓ(R²)ₓ where each R¹ group is selected from a hydroxyl or a hydrolyzable group and each R² group is selected from a non-hydrolyzable group. There is at least one R¹ group. That is, there can be one R¹ group and two R² groups, two R¹ groups and one R² group, or three R¹ groups and no R² group. When there are multiple R¹ groups, they can be the same or different. Likewise, when there are multiple R² groups, they can be the same or different. In many embodiments, there are three identical R¹ groups.

The term “hydrolyzable group” refers to a group that can react with water having a pH of 1 to 10 under conditions of atmospheric pressure. The hydrolyzable group is usually converted to a hydroxyl group when it reacts. The hydroxyl group often undergoes further reactions such as with a siliceous substrate. Typical hydrolyzable groups include alkoxy, aryloxy, aralkyloxy, acyloxy, and halo groups.

Suitable alkoxy R¹ groups include, but are not limited to, those of formula —OR^{a} where R^{a} is an alkyl group having 1 to 10 carbon atoms, 1 to 6 carbon atoms, 1 to 4 carbon atoms, 1 to 3 carbon atoms, or 1 to 2 carbon atoms. The alkyl portion of the alkoxy group can be linear, branched, cyclic, or a combination thereof. In many embodiments of Formula (I), each R¹ group is an alkoxy having 1 to 4 carbon atoms or 1 to 3 carbon atoms.

Suitable aryloxy R¹ groups include, but are not limited to, those of formula —OAr where Ar is an aryl group. The aryl group is monovalent group having at least one carbocyclic aromatic ring. Additional carbocyclic rings can be fused to the aromatic ring. Any additional rings can be unsaturated, partially saturated, or saturated. The aryl portion of the aryloxy group often has 6 to 12 carbon atoms or 6 to 10 carbon atoms. In many embodiments, the aryloxy group is phenoxy.

Suitable aralkyloxy R¹ groups include, but are not limited to, those of formula —OR^{b}—Ar. The group R^{b} is a divalent alkylene group (i.e., divalent radical of an alkane), having 1 to 10 carbon atoms, 1 to 6 carbon atoms, or 1 to 4 carbon atoms. The alkylene can be linear, branched, cyclic, or a combination thereof. The group Ar is an aryl group having at least one carbocyclic aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl group is often phenyl.

Suitable acyloxy R¹ groups include, but are not limited to, those of formula —O(CO)R where R^{c} is alkyl, aryl, or aralkyl. The group (CO) denotes a carbonyl group. Suitable alkyl R^{c} groups often have 1 to 10 carbon atoms, 1 to 6 carbon atoms, or 1 to 4 carbon atoms. The alkyl can be linear, branched, cyclic, or a combination thereof. Suitable aryl R^{c} groups are carbocyclic and have at least one aromatic ring. Additional carbocyclic rings can be fused to the aromatic ring. Any additional rings can be unsaturated, partially saturated, or saturated. The aryl group usually has 6 to 12 carbon atoms or 6 to 10 carbon atoms. The aryl group is often phenyl. Suitable aralkyl R^{c} groups often have an alkylene group with 1 to 10 carbon atoms, 1 to 6 carbon atoms, or 1 to 4 carbon atoms and an aryl group with 6 to 12 carbon atoms, or 6 to 10 carbon atoms. The alkylene portion of the aralkyl group can be linear, branched, cyclic, or a combination thereof. The aryl portion of the aralkyl group has at least one carbocyclic aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl portion of the aralkyl group is often phenyl.

Suitable halo R¹ groups include, but are not limited to: be bromo, iodo, or chloro groups. The halo is often chloro.

Each R² group in Formulas (I) is a non-hydrolyzable group. The term “non-hydrolyzable group” refers to a group that does not react with water having a pH of 1 to 10 under conditions of atmospheric pressure. In many embodiments, the non-hydrolyzable group is an alkyl, aryl, or aralkyl group. Suitable alkyl R² groups include those having 1 to 10 carbon atoms, 1 to 6 carbon atoms, or 1 to 4 carbon atoms. The alkyl can be linear, branched, cyclic, or a combination thereof. Suitable aryl R² groups are carbocyclic and have at least one aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl group is often phenyl. Suitable aralkyl R² groups often have an alkylene group having 1 to 10 carbon atoms, 1 to 6 carbon atoms, or 1 to 4 carbon atoms and an aryl group with 6 to 12 carbon atoms, or 6 to 10 carbon atoms. The alkylene portion of the aralkyl group can be linear, branched, cyclic, or a combination thereof. The aryl portion of the aralkyl group has at least one carbocyclic aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl portion of the aralkyl group is often phenyl.

Methods of preparing the compounds of Formulas (IA) are known. These fluorinated silanes can be prepared by initially preparing a fluorinated methyl ester of Formula (II) where n is the same as defined for Formula (I).

F(CF(CF₃)CF₂O)ₙCF(CF₃)—(CO)OCH₃ (II)

This fluorinated methyl ester of Formula (II) can be prepared by several methods. In a first method, the fluorinated methyl ester is prepared by metal fluoride-initiated oligomerization of hexafluoropropylene oxide in diglyme (i.e. bis(2-methoxyethyl) ether) solvent according to the method described in U.S. Pat. No. 3,250,808 (Moore et al.), the description of which is incorporated herein by reference. The fluorinated methyl ester can be purified by distillation to remove low-boiling components. Other solvents can also be used in addition to those described in Moore et al. including hexafluoropropene, 1,1,1,3,3-pentafluorobutane and 1,3-bis(trifluoromethyl)benzene as described by S. V. Kostjuk et al. in Macromolecules, 42, 612-619 (2009).

Alternatively, the fluorinated methyl ester of Formula (II) can also be prepared from the corresponding fluorinated carboxylic acid of Formula (III).

F(CF(CF₃)CF₂O)ₙCF(CF₃)—(CO)OH (III)

Suitable fluorinated carboxylic acids are commercially available under the trade designation KRYTOX (e.g., KYTOX 157FS(H)). The fluorinated carboxylic acid can be reacted with a chlorinating agent such as thionyl chloride or oxalyl chloride to form the corresponding fluorinated carboxylic acid chloride. The fluorinated carboxylic acid chloride can be subsequently reacted with methanol to form the fluorinated methyl ester of Formula (II).

The fluorinated methyl ester of Formula (II) can then be reduced with sodium borohydride to a fluorinated alcohol of Formula (IV).

F(CF(CF₃)CF₂O)ₙCF(CF₃)—CH₂OH (IV)

The fluorinated alcohol of Formula (IV) can be reacted with allyl bromide to form the fluorinated allyl ether of Formula (V).

F(CF(CF₃)CF₂O)ₙCF(CF₃)—CH₂OCH₂CH═CH₂ (V)

The fluorinated allyl ether of Formula (V) can then be reacted with trichlorosilane to form a fluorinated silane with a trichlorosilyl group. The trichlorosilyl group can be reacted with an alcohol such as methanol to form a trialkoxysilyl group (e.g., a trimethoxysilyl group as in Formula (VI)).

F(CF(CF₃)CF₂O)ₙCF(CF₃)—CH₂OCH₂CH₂CH₂—Si(OMe)₃ (VI) Methods of preparing the compounds of Formula (IB) are known. These fluorinated silanes can be prepared, for example, as described in U.S. Pat. No. 7,294,731 B1 (Flynn et al.). More specifically, the fluorinated allyl ether of Formula (V) above can be reacted with a mercaptosilane such as, for example, HSC₃H₆Si(OCH₃)₃.

In addition to the fluorinated silane of Formula (I), the hexafluoropropylene oxide derived silane coating composition can include an optional crosslinker. The crosslinker typically has two or more reactive silyl groups (i.e., a reactive silyl group is one that has at least one hydroxyl or hydrolyzable group). These silyl groups of the crosslinker can react with any reactive silyl group of the fluorinated silane that has not reacted with the siliceous substrate. Alternatively, a first group of the crosslinker can react with the siliceous substrate and a second group of the crosslinker can react with a reactive silyl group of the fluorinated silane. In this alternative reaction, the crosslinker can function as a linker between the fluorinated silane and the siliceous substrate.

Some crosslinkers have multiple reactive silyl groups. Some crosslinkers can be polymers with multiple silyl groups. One such polymer is poly(diethoxysilane). Other crosslinkers can be of Formula (XII) or Formula (XIII).

Si(R³)_{4-y}(R⁴)_{y} (VII)

R⁵—[Si(R⁶)_{3-z}(R⁷)_{z}]₂ (VIII)

In Formula (VII) or (VIII), each R³ or R⁶ is independently hydroxyl or a hydrolyzable group and each R⁴ or R⁷ is independently a non-hydrolyzable group. The variable y in Formula (VII) is an integer in a range of 0 to 3 (i.e., 0, 1, 2, or 3). The variable z in Formula (VIII) is an integer in a range of 0 to 2 (i.e., 0, 1, or 2). The group R⁵ in Formula (VIII) is an alkylene having 1 to 10 carbon atoms, 1 to 6 carbon atoms, 1 to 4 carbon atoms, or 1 to 3 carbon atoms. The alkylene R⁵ can be linear, branched, cyclic, or a combination thereof.

Each R³ or R⁶ group in Formulas (VII) or (VIII) respectively is a hydroxyl or hydrolyzable group. This group can react with a remaining reactive silyl in a fluorinated silane. Reacting multiple such R³ or R⁶ groups with multiple fluorinated silanes can result in the crosslinking of the fluorinated silanes. Alternatively, one such group can also react with the surface of a siliceous substrate and another such group can react with a fluorinated silane to covalently attach the fluorinated silane to the siliceous substrate. Suitable hydrolyzable R³ or R⁶ groups include, for example, alkoxy, aryloxy, aralkyloxy, acyloxy, or halo groups.

Suitable alkoxy R³ or R⁶ groups are of formula —OR^{a} where R^{a} is an alkyl group having 1 to 10 carbon atoms, 1 to 6 carbon atoms, 1 to 4 carbon atoms, 1 to 3 carbon atoms, or 1 to 2 carbon atoms. The alkyl portion of the alkoxy group can be linear, branched, cyclic, or a combination thereof. In many embodiments of Formula (I), each R³ or R⁶ group is an alkoxy having 1 to 4 carbon atoms or 1 to 3 carbon atoms.

Suitable aryloxy R³ or R⁶ groups are of formula —OAr where Ar is an aryl group. The aryl group is monovalent group having at least one carbocyclic aromatic ring. Additional carbocyclic rings can be fused to the aromatic ring. Any additional rings can be unsaturated, partially saturated, or saturated. The aryl portion of the aryloxy group often has 6 to 12 carbon atoms or 6 to 10 carbon atoms. In many embodiments, the aryloxy group is phenoxy.

Suitable aralkyloxy R³ or R⁶ groups are of formula —OR^{b}—Ar. The group R^{b} is a divalent alkylene group having 1 to 10 carbon atoms, 1 to 6 carbon atoms, or 1 to 4 carbon atoms and an aryl portion with 6 to 12 carbon atoms, or 6 to 10 carbon atoms. The alkylene can be linear, branched, cyclic, or a combination thereof. The group Ar is an aryl group having at least one carbocyclic aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl group is often phenyl.

Suitable acyloxy R³ or R⁶ groups are of formula —O(CO)R where R^{c} is alkyl, aryl, or aralkyl. The group (CO) denotes a carbonyl group. Suitable alkyl R^{c} groups often have 1 to 10 carbon atoms, 1 to 6 carbon atoms, or 1 to 4 carbon atoms. The alkyl can be linear, branched, cyclic, or a combination thereof. Suitable aryl R^{c} groups are carbocyclic and have at least one aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl group is often phenyl. Suitable aralkyl R^{c} groups often have an alkylene group having 1 to 10 carbon atoms, 1 to 6 carbon atoms, or 1 to 4 carbon atoms and an aryl group with 6 to 12 carbon atoms, or 6 to 10 carbon atoms. The alkylene portion of the aralkyl group can be linear, branched, cyclic, or a combination thereof. The aryl portion of the aralkyl group has at least one carbocyclic aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl portion of the aralkyl group is often phenyl.

Suitable halo R³ or R⁶ groups include, but are not limited to: be bromo, iodo, or chloro groups. The halo is often chloro.

Each R⁴ or R⁷ group in Formulas (VII) or (VIII) respectively is a non-hydrolyzable group. Many non-hydrolyzable groups are alkyl, aryl, and aralkyl groups. Suitable alkyl R⁴ or R⁷ groups include those having 1 to 10 carbon atoms, 1 to 6 carbon atoms, or 1 to 4 carbon atoms. The alkyl can be linear, branched, cyclic, or a combination thereof. Suitable aryl R⁴ or R⁷ groups are carbocyclic and have at least one aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl group is often phenyl. Suitable aralkyl R⁴ or R⁷ groups often have an alkylene group having 1 to 10 carbon atoms, 1 to 6 carbon atoms, or 1 to 4 carbon atoms and an aryl group with 6 to 12 carbon atoms, or 6 to 10 carbon atoms. The alkylene portion of the aralkyl group can be linear, branched, cyclic, or a combination thereof. The aryl portion of the aralkyl group has at least one carbocyclic aromatic ring. Additional carbocyclic rings can be fused to the aromatic ring. Any additional rings can be unsaturated, partially saturated, or saturated. The aryl group often has 6 to 12 carbon atoms or 6 to 10 carbon atoms. The aryl portion of the aralkyl group is often phenyl.

Example crosslinkers include, but are not limited to, tetraalkoxysilanes such as tetraethoxysilane (TEOS) and bis(triethoxysilyl)ethane.

If included in the curable coating composition, the weight ratio of the crosslinker to the fluorinated silane (crosslinker: fluorinated silane) is often at least 0.5:100, at least 1:100, at least 2:100, or at least 5:100. The weight ratio can be up to 30:100, up to 20:100, or up to 10:100. For example, the weight ratio of crosslinker to fluorinated silane can be in a range of 0.5:100 to 30:100, in a range of 1:100 to 20:100, or in a range of 1:100 to 10:100.

Any of the coating compositions can include an optional solvent that is usually a fluorinated solvent. The fluorinated solvent is typically miscible with the fluorinated silane or with both the fluorinated silane and the fluorinated polyether oil. The fluorinated solvents may include, but are not limited to, perfluorinated hydrocarbons such as, for example, perfluorohexane, perfluoroheptane and perfluorooctane; fluorinated hydrocarbons such as, for example, pentafluorobutane, perfluorohexylethene (C₆F₁₃CH═CH₂), perfluorobutylethene (C₄F₉CH═CH₂), C₄F₉CH₂CH₃, C₆F₁₃CH₂CH₃, C₆F₁₃H, C₂F₅CH═CHC₄F₉, or 2,3-dihydrodecafluoropentane; hydrofluoroethers such as, for example, methyl perfluorobutyl ether, ethyl perfluorobutyl ether, CF₃CH₂OCF₂CF₂H, and C₂F₅CF=CFCF(OC₂H₅)C₂F₅; and combinations thereof. Some hydrofluoroethers are commercially available from 3M Company (Saint Paul, Minn.) under the trade designation 3M NOVEC™ ENGINEERED FLUID (e.g., 3M NOVEC™ ENGINEERED FLUID 7000, 7100, 7200, 7200DL, 7300, 7500, 71DE and 71DA).

The fluorinated solvent may contain small amounts of optional organic solvents which are miscible with the fluorinated solvent. For example, the solvent (i.e., fluorinated solvent plus optional organic solvent) can include up to about 10 weight percent, up to about 8 weight percent, up to about 6 weight percent, up to about 4 weight percent, up to about 2 weight percent, or up to about 1 weight percent organic solvent based on a total weight of solvent. Suitable organic solvents for combining with the fluorinated solvent include, but are not limited to, aliphatic alcohols such as, for example, methanol, ethanol, and isopropanol; ketones such as, for example, acetone and methyl ethyl ketone; esters such as, for example, ethyl acetate and methyl formate; ethers such as, for example, diethyl ether, diisopropyl ether, methyl t-butyl ether, and dipropylene glycol monomethyl ether (DPM); chlorinated hydrocarbons such as trans-dichloroethylene; alkanes such as, for example, heptane, decane, and other paraffinic (i.e., olefinic) organic solvents. Preferred organic solvents often include aliphatic alcohols such as ethanol and isopropanol.

If a solvent (i.e., a fluorinated solvent plus any optional organic solvent) is added to the coating composition, any suitable amount of the solvent can be used. Typically, the other components of the coating composition such as the fluorinated silane are dissolved in the solvent. The amount of solvent can also be selected to provide the desired viscosity for application of the curable coating composition to a siliceous substrate. Some example coating compositions contain up to about 50 weight percent, up to about 60 weight percent, up to about 70 weight percent, up to about 75 weight percent, up to about 80 weight percent, up to about 90 weight percent, up to about 95 weight percent, up to about 98 weight percent, or up to about 99.9 weight percent solvent. Some example curable coating compositions contain at least about 1 weight percent, at least about 5 weight percent, at least about 10 weight percent, at least about 15 weight percent, at least about 20 weight percent, at least about 25 weight percent, or at least about 30 weight percent solvent. For example, the curable coating compositions can include about 1 to about 99.9 weight percent, about 1 to about 95 weight percent, about 5 to about 90 weight percent, about 10 to about 90 weight percent, about 20 to about 90 weight percent, about 30 to 9 about 0 weight percent, about 40 to about 90 weight percent, about 50 to about 90 weight percent, about 50 to about 85 weight percent, or about 60 to about 85 weight percent solvent.

In some embodiments, the polymeric hexafluoropropylene oxide derived silane coating composition can be provided in the form of a concentrate that includes a fluorinated silane of Formula (I) and a fluorinated solvent. The concentrate contains up to about 99 weight percent, up to about 98 weight percent, up to about 95 weight percent, up to about 90 weight percent, up to about 85 weight percent, up to about 80 weight percent, up to about 75 weight percent, or up to about 70 weight percent fluorinated solvent based on a total weight of the concentrate.

In some embodiments, an optional moisture curing catalyst is included in the polymeric coating composition. Suitable moisture curing catalysts are those that are soluble in the polymeric coating composition (e.g., in the fluorinated solvent or in the combination of fluorinated solvent plus optional organic solvent) and can include, for example, ammonia, N-heterocyclic compounds, monoalkylamines, dialkylamines, or trialkylamines, organic or inorganic acids, metal carboxylates, metal acetylacetonate complexes, metal powders, peroxides, metal chlorides, organometallic compounds, and the like, and combinations thereof. When used, the moisture curing catalysts are used in amounts that are soluble in the curable coating compositions. In some embodiments, the moisture curing agents are present in an amount in a range of about 0.1 to about 10 weight percent, in a range of about 0.1 to about 5 weight percent, or in a range of about 0.1 to about 2 weight percent based on a total weight of the curable coating composition.

Example N-heterocyclic compounds that can function as moisture curing catalysts include, but are not limited to: 1-methylpiperazine, 1-methylpiperidine, 4,4′-trimethylenedipiperidine, 4,4′-trimethylene-bis(1-methylpiperidine), diazobicyclo[2.2.2]octane, cis-2,6-dimethylpiperazine, and the like, and combinations thereof. Example monoalkylamines, dialkylamines, and trialkylamines that can function as moisture curing catalysts include, but are not limited to, methylamine, dimethylamine, trimethylamine, phenylamine, diphenylamine, triphenylamine, DBU (that is, 1,8-diazabicyclo[5.4.0]-7-undecene), DBN (that is, 1,5-diazabicyclo[4.3.0]-5-nonene), 1,5,9-triazacyclododecane, 1,4,7-triazacyclononane, and the like, and combinations thereof.

Example organic or inorganic acids that can function as moisture curing catalysts include, but are not limited to, acetic acid, formic acid, triflic acid, trifluoroacetic acid, perfluorobutyric acid, propionic acid, butyric acid, valeric acid, maleic acid, stearic acid, citric acid, hydrochloric acid, nitric acid, sulfuric acid, phosphoric acid, chloric acid, hypochlorous acid, and the like, and combinations thereof.

In another aspect, an article is provided that contains a) a siliceous substrate and b) a layer of a curable coating composition adjacent to the siliceous substrate. The polymeric coating compositions are any of those described herein.

Siliceous substrates include those formed of various materials that contain silicon distributed throughout the substrate. Examples of siliceous substrates include, but are not limited to: glass, ceramic materials, glazed ceramic materials, concrete, mortar, grout, and natural or man-made stone. The siliceous substrate can be, for example, part of an electronic display (e.g., an outer surface of an electronic display such as a touch screen), mirror, window, windshield, ceramic tile, shower stall, toilet, sink, or the like. In many embodiments, the siliceous substrate is transparent, which means that it is possible to see through the siliceous substrate with an unaided human eye. The transparent substrate can be clear or colored.

In yet another aspect, a method of making a fluorinated surface is provided. The method includes providing a siliceous substrate and disposing a coating composition adjacent to the siliceous substrate. Any coating composition described herein can be used. The method further includes reacting the coating composition with a surface of the siliceous substrate to form a coating composition. The coating composition on the siliceous substrate can provide, for example, abrasion resistant surfaces, easy to clean surfaces, surfaces with good tactile response (i.e., a finger can easily slide over the surface), or a combination thereof.

Coatings that include the hexafluoropropylene oxide derived silane polymer of the present invention may be applied to various substrates, particularly hard substrates, to render them oil-, water-, and soil repellent. The polymeric coating composition can be applied to the siliceous substrate using any suitable application method. In some embodiments, the polymeric coating compositions are applied using a vapor deposition method. In other embodiments, the coating compositions are applied using a technique such as spray coating, knife coating, dip coating, spin coating, meniscus coating, or the like.

Vapor deposition methods can be used alone or in combination with other application methods. In some embodiments, the hexafluoropropylene oxide derived silane polymer is vapor deposited on the siliceous substrate. The solution can be applied using various coating methods such as spray coating, knife coating, dip coating, spin coating, or meniscus coating as described below.

When vapor deposition is used for deposition of the hexafluoropropylene oxide derived silane polymer, the siliceous substrate is typically placed within a vacuum chamber. After the pressure has been reduced, the fluorinated silane is vaporized within the vacuum chamber. The hexafluoropropylene oxide derived silane polymer can be placed in a crucible or imbibed in a porous pellet that is heated within the vacuum chamber. The conditions used for vapor deposition depend on the molecular weight of the hexafluoropropylene oxide derived silane polymer. In some embodiments, the pressure during deposition is less than about 10⁻² torr, less than about 10⁻³ torr, less than about 10⁻⁴ torr, or less than about 10⁻⁵ torr. If a fluorinated solvent is included in the coating composition, the fluorinated solvent is typically removed as the pressure within the vacuum chamber is lowered. The coating temperature is selected based on the boiling point of the materials that are deposited. Typically, a coating temperature at or above the boiling point but below the decomposition temperature is selected. Suitable temperatures are often at least about 100° C., at least about 150° C., at least about 200° C., or at least about 250° C.

When coating techniques such as spray coating, knife coating, dip coating, spin coating, or meniscus coating are used, the coating composition typically includes a fluorinated solvent. The percent solids of the coating composition are usually selected to provide a suitable solution viscosity for the particular application method and to dissolve the various components of the coating composition such as the fluorinated silane. In many application methods, the percent solids are no greater than about 50 weight percent, no greater than about 40 weight percent, no greater than about 30 weight percent, no greater than about 25 weight percent, no greater than about 20 weight percent, no greater than about 15 weight percent, no greater than about 10 weight percent, or no greater than about 5 weight percent. The percent solids are usually at least about 0.1 weight percent, at least about 1 weight percent, at least about 2 weight percent, or at least about 5 weight percent. The solids include the hexafluoropropylene oxide derived silane polymer and any other materials dissolved or suspended in the fluorinated solvent.

The polymeric coating composition is usually applied to the siliceous substrate at room temperature (in a range of about 15° C. to about 30° C. or in a range of about 20° C. to about 25° C.). Alternatively, the coating composition can be applied to the siliceous substrate that has been preheated at an elevated temperature such as, for example, in a range of about 40° C. to about 300° C., in a range of about 50° C. to about 200° C., or in a range of about 60° C. to about 150° C.

Suitable substrates that can be treated in with the perfluoropolyether silane coating composition include substrates having a hard surface preferably with functional groups capable of reacting with the hexafluoropropylene oxide derived silane polymer. Preferably, such reactivity of the surface of the substrate is provided by active hydrogen atoms. When such active hydrogen atoms are not present, the substrate may first be treated in a plasma containing oxygen or in a corona atmosphere to make it reactive.

Treatment of the substrates results in rendering the treated surfaces less retentive of soil and more readily cleanable due to the oil and water repellent nature of the treated surfaces. These desirable properties are maintained despite extended exposure or use and repeated cleanings because of the high degree of durability of the treated surface as can be obtained through the compositions of this invention.

The substrate may be cleaned prior to applying the compositions of the invention so as to obtain optimum characteristics, particularly durability. That is, the surface of the substrate to be coated should be substantially free of organic contamination prior to coating. Cleaning techniques depend on the type of substrate and include, for example, a solvent washing step with an organic solvent, such as acetone or ethanol.

In still another aspect, an article is provided that contains a) a siliceous substrate and b) a layer of a coating composition adjacent to the siliceous substrate. The coating composition includes a reaction product of a coating composition with a surface of the siliceous substrate. Any coating composition described herein can be used to form the coating composition.

As used herein, the term “curing” refers to the reaction of the silyl group of the hexafluoropropylene oxide derived silane polymer with the siliceous substrate. As used herein, the term “cured coating composition” refers to a coating composition that has undergone curing. The curing reaction results in the formation of a —Si—O—Si— group and the covalent attachment of the hexafluoropropylene oxide derived silane polymer to the siliceous substrate. In this siloxane group, one silicon atom is from the silyl group of the hexafluoropropylene oxide derived silane polymer and the other silicone atom is from the siliceous substrate.

Following application using any method, the polymeric coating composition can be dried to remove solvent and then cured at ambient temperature (for example, in the range of about 15° C. to about 30° C. or in the range of about 20° C. to about 25° C.) or at an elevated temperature (for example, in the range of about 40° C. to about 300° C., in the range of about 50° C. to about 250° C., in the range of about 50° C. to about 200° C., in the range of about 50° C. to about 175° C., in the range of about 50° C. to about 150° C., in the range of about 50° C. to about 125° C., or in the range of about 50° C. to about 100° C.) for a time sufficient for curing to take place. The sample is often held at the curing temperature for at least about 10 minutes, at least about 20 minutes, at least about 30 minutes, at least about 40 minutes, at least about 1 hour, at least about 2 hours, at least about 4 hours, or at least about 24 hours. The drying and curing steps can occur concurrently or separately by adjustment of the temperature.

Curing often occurs in the presence of some water. Sufficient water is often present to cause hydrolysis of the hydrolyzable groups described above, so that condensation to form —Si—O—Si—groups can occur (and thereby curing can be achieved). The water can be present in the atmosphere (for example, an atmosphere having a relative humidity of about 20 percent to about 70 percent), on the surface of the siliceous substrate, in the curable coating composition, or a combination thereof.

The cured coatings can have any desired thickness. This thickness is often in a range of about 2 to about 20 nanometers. For example, the thickness can be in a range about 2 to about 20, about 2 to about 10, or about 4 to about 10 nanometers.

The articles having a polymeric coating composition of the present invention often have improved abrasion resistance compared to the uncoated siliceous substrate. The coated siliceous substrate can be abraded with steel wool (e.g., steel wool No. 0000 that is capable of scratching a glass surface) while retaining water repellant and/or oil repellant properties of the cured coating. The coated siliceous substrate typically has a lower coefficient of friction compared to the uncoated siliceous substrate. This lower coefficient of friction may contribute to the improved abrasion resistance of the coated siliceous substrate.

The articles having a polymeric coating composition of the present invention provide a good tactile response. That is, a finger can slide over the surface of the articles easily. This is particularly desirable when the article is used in electronic displays such in touch screens.

The articles have an easy to clean surface. This easy to clean surface is provided by the use of fluorinated materials in the curable coating composition. The surfaces of the articles with cured coating compositions tend to be hydrophobic. The contact angle for water is often equal to at least about 85 degrees, at least about 90 degrees, at least about 95 degrees, at least about 100 degrees, at least about 105 degrees, at least about 110 degrees, or at least about 115 degrees.

In one embodiment, the article being coated with the composition of the present invention is a consumer electronic device. Consumer electronic devices includes, but is not limited to: personal computers (portable and desktop); tablet or slate style computing devices; handheld electronic and/or communication devices (e.g., smartphones, digital music players, multi-function devices, etc.); any device whose function includes the creation, storage or consumption of digital media; or any component or sub-component in any consumer electronic product.

Various items are provided that are curable coating compositions, articles that include the curable coating compositions, articles that include a cured coating composition, and method of making the articles with the cured coating composition.

### EXAMPLES

Objects and advantages of this invention are further illustrated by the following examples, but the particular materials and amounts thereof recited in these examples, as well as other conditions and details, should not be construed to unduly limit this invention. These examples are for illustrative purposes only and are not meant to be limiting on the scope of the appended claims.

### Materials

All solvents were standard reagent grade obtained from commercial sources and were used without further purification unless specified otherwise.

“Float glass plate” refers to a float glass pane that was obtained from Cardinal Glass Industries (Eden Prairie, Minn., USA). One side of the glass plate has a tin surface layer.

“Chemically strengthened glass plate” refers to alkali-aluminosilicate glass available from Corning Incorporated.

“HFPO” refers to hexafluoropropylene oxide.

“PF-5060DL™ refers to a fully fluorinated liquid that is commercially available from 3M Company (Saint Paul, Minn., USA) under trade designation 3M PERFORMANCE FLUID PF-5060DL™

“NOVEC™ 7100” refers to a hydrofluoroether solvent that is commercially available from 3M Company (Saint Paul, Minn., USA) under trade designation 3M NOVEC™ ENGINEERED FLUID 7100. “NOVEC™ 7200DL” and “NOVEC™ 7200” refers to hydrofluoroether solvents that are commercially available from 3M Company (Saint Paul, Minn., USA) under trade designation 3M NOVEC™ ENGINEERED FLUID 7200DL and 3M NOVEC™ ENGINEERED FLUID 7200.

“NOVEC™ 7300” refers to a hydrofluoroether solvent that is commercially available from 3M Company (Saint Paul, Minn., USA) under trade designation 3M NOVEC™ ENGINEERED FLUID 7300.

### Deposition Method

Two types of glass plates were used for testing: float glass or chemically strengthened glass. They will be referred to as “float glass” or “chemically strengthened glass” throughout the examples section.

When preparing float glass plate samples, the side of each glass plate substrate bearing the tin surface layer was identified using fluorescence under UV light and marked as the “back”. Coatings according to the examples described below were deposited only on the front or air side of the glass plates (substrates).

When preparing chemically strengthened glass plate samples, both sides of the glass had the same composition and do not require identification of a “front” or “back” side.

Prior to use, all types of glass plate substrates were cleaned by one or more methods.

The first method included wetting the surface of glass with isopropyl alcohol (IPA) and wiping all surfaces including the edges of the glass plate using a soft woven cloth (commercially available from VWR North America (Batavia, Ill., USA) under the trade designation SPEC-WIPE 4 (catalog number 21912-046).

The second method included immersing the glass plate substrates for 10 minutes in a stirred mixture of 4 parts concentrated sulfuric acid and one part 30 percent hydrogen peroxide that was heated to approximately 100° C. Upon removal from the cleaning mixture, the glass plates were placed in a deionized water bath and then rinsed under a stream of deionized water. The glass plates were then dried under a stream of nitrogen and coated within approximately 30 minutes.

The third method included immersing the glass plate substrates for 10 minutes in a stirred mixture of 1 part 30% ammonium hydroxide, 2 parts 30 percent hydrogen peroxide and 20 parts deionized water. The mixture was heated to approximately 50° C. Upon removal from the cleaning mixture, the glass plates were placed in a deionized water bath and then rinsed under a stream of deionized water. The glass plates were then dried under a stream of nitrogen and coated within approximately 30 minutes.

The coatings were applied using a spray gun, which is commercially available as part number RG-3L-3S from Anest Iwata (Yokohama, Japan). Enough fluid was applied to completely coat the glass surface. After spray coating, the coated glass plates were cured in an oven heated to at least 135° C. for a time as specified in each example below. After curing, the coated glass plates were allowed to cool and rest for a minimum of 16 hours before any subsequent testing.

### Method for Measuring Contact Angle

Coated substrates were prepared as described in the following examples using the deposition method as described above.

The coated substrates were wiped with a woven cloth (commercially available from VWR North America (Batavia, Ill., USA) under the trade designation SPEC-WIPE 4™ (catalog number 21912-046) that was moistened with isopropyl alcohol (IPA). The IPA was allowed to evaporate before measuring water (H₂O) and hexadecane (HD) contact angles (using water and hexadecane, respectively, as wetting liquids).

Measurements were made using as-received, reagent-grade hexadecane and filtered deionized water on a Kruss video contact angle analyzer that is available as product number DSA 100S from Kruss GmbH (Hamburg, Germany). Reported values are the averages of measurements on at least three drops. Drop volumes were 5 microliters for static water contact angle measurements and 4 microliters for static hexadecane contact angle measurements.

### Method for Measuring Abrasion

A TABER 5900 linear abrader, which was obtained from Taber Industries of North Tonawanda (NY, USA), was used to conduct one of two abrasion test methods.

The first abrasion test method included using a 1 inch diameter round aluminum tool available from Taber Industries. Steel wool (No. 0000) was cut to a square approximately 1 inch by 1 inch and secured to the abrasion tool using double sided tape.

The second abrasion test method included using a 1 centimeter by 1 centimeter square tool available from Taber Industries. Steel wool (No. 0000 that is capable of scratching the surface of glass) was cut to approximately 20 millimeters by 40 millimeters in size, folded over once and placed between the square tool and the coated glass substrates to be tested. The grain of the steel wool was aligned such that the grain was parallel to the linear abrasion direction.

The samples were abraded in increments of at least 1,000 cycles at a rate of 60 cycles/minute (1 cycle consisted of a forward wipe followed by a backward wipe) with a force of either 2.5 Newtons (N) (using the first abrasion method above) or 10 Newtons (N) (using the second abrasion method above) and a stroke length of 70 millimeters. After each 1000 cycles (or as specified otherwise) of abrasion, the coated substrates were cleaned with IPA. Both water and hexadecane (HD) contact angle measurements made. The same coated substrate was cleaned again with IPA and subjected to another 1000 cycles (or as specified otherwise) of abrasion. A given set of samples was abraded using either the first or second abrasion method, they were not abraded with a combination of methods.

### Method for Measuring Coefficient of Friction

The coefficient of friction (CoF) was measured on the coated glass substrates using a modification of the method described in ASTM D1894-08 (Standard Test Method for Static and Kinetic Coefficients of Friction of Plastic Film and Sheeting).

Measurements of CoF were obtained using an Extended Capability Slip/Peel Tester, model# SP-102B-3M-90 (Instrumentors, Inc., Strongsville, Ohio). This piece of equipment was located in a constant temperature and humidity test room maintained at 70 plus/minus 3° F. and 50 plus/minus 5% RH.

Pieces of float glass (5 in×10 in×0.125 in) were cleaned as described above using the first method followed by the second method. Cleaned substrates were then coated and cured as described above. Coated substrates were placed in the constant temperature and humidity test room and allowed to equilibrate for a minimum of 18 hours prior to testing.

Poron® ThinStick polyurethane foam, p/n 4790-92TS1-12020-04 from Rogers Corporation (Rogers, Conn.) was used as the material adhered to the sled (per the test method procedure), contacting the coated glass substrate. Pieces of the foam were cut into squares (2.5 in ×2.5 in) and placed in the constant temperature and humidity test room and allowed to equilibrate for a minimum of 18 hours prior to testing.

The CoF was measured following the procedure specified in ASTM D1894-08. The coated substrate was adhered to the plane, coated side up, using double sided tape. The foam was adhered to the sled (foam side up) using double sided tape. The sled with foam attached was placed on the coated substrate and measured as described in the ASTM with the sled held stationary and the plane moving underneath at a rate of 12 inches per minute. The reported CoF data was based on the mean of at least 3 measurements made in succession using the same piece of foam and the same coated substrate. A new piece of foam was used for each coated substrate.

### Preparation 1: Preparation of HFPO-Derived Methyl Ester

The methyl ester F(CF(CF₃)CF₂O)ₐCF(CF₃)C(O)OCH₃, wherein the variable a has an average value in a range of 4 to 100, was prepared by metal fluoride-initiated oligomerization of hexafluoropropylene oxide in diglyme solvent according to the method described in U.S. Pat. No. 3,250,808 (Moore et al.), the description of which is incorporated herein by reference. The product was purified by distillation to remove low-boiling components. Several different number average molecular weight materials were prepared and converted to the corresponding allyl ethers following the chemistry described in the following preparative examples.

Other solvents could also be used in addition to those described in Moore et al. including hexafluoropropene, 1,1,1,3,3-pentafluorobutane and 1,3-bis(trifluoromethyl)benzene as described by S. V. Kostjuk et al. in Macromolecules, 42, 612-619 (2009).

Alternatively, the methyl ester could also be prepared as described below in Preparation 2 from the corresponding commercially available carboxylic acid.

### Preparation 2: Preparation of HFPO-Derived Methyl Ester from HFPO-Derived Carboxylic Acid

KRYTOX 157FS(H) (249.9 grams, 0.042 moles, M_{N}=5900, C₃F₇O[CF(CF₃)CF₂O]ₙCF(CF₃)CO₂H, available from E. I. Du Pont de Nemours & Co. (Wilmington, Del., USA)) and dimethyl formamide (5.0 grams, 0.069 moles) were added to a 500 mL, three-necked round bottom flask equipped with an overhead stirrer and a water condenser topped with a nitrogen tee leading to a source of dry nitrogen and a scrubber containing a dilute solution of aqueous potassium carbonate. The mixture was heated to 75° C. and then thionyl chloride (10.1 grams, 0.085 moles, obtained from Aldrich Chemical Company, Milwaukee, Wis.) was added by pipette through the third neck of the flask. (An equivalent amount of oxalyl chloride could be substituted for the thionyl chloride with the reaction run at 65° C.). Gas evolution was observed and the reaction was stirred for an additional 16 hours at 75° C. The product was HFPO-derived carboxylic acid chloride.

At the end of this time, methanol (25 mL) was added to the reaction mixture to convert the HFPO-derived carboxylic acid chloride to the methyl ester. The reaction mixture was stirred for an additional hour at 75° C. After the mixture had cooled, the resulting two phase system was separated. The lower product phase was dissolved in PF-5060DL (200 mL) and washed once with acetone (25 mL). The solution was filtered through a DRYDISK Separation Membrane with a GORE-TEX process filtration media that is available from Horizon Technology, Inc. (Salem, N.H., USA). The solvent was removed by rotary evaporation to afford C₃F₇O[CF(CF₃)CF₂O]ₙCF(CF₃)CO₂C H₃ with a yield in excess of 98 percent.

### Preparation 3: Preparation of HFPO-Derived Alcohol from HFPO-Derived Methyl Ester

The HFPO-derived methyl ester C₃F₇O[CF(CF₃)CF₂O]ₙCF(CF₃)CO₂CH₃ (M_{N}=5900, 195.5 grams, 0.033 moles), NOVEC™ 7100 (293 grams) and tetrahydrofuran (60 grams) were placed within a 1 L, three-necked round bottom flask equipped with an overhead stirrer. The solution was cooled in an ice bath to about 3° C. Sodium borohydride (5.16 grams, 0.136 moles), which was obtained from Aldrich Chemical Company (Milwaukee, Wis., USA), was added to the solution. When the temperature had reached 1° C., anhydrous methanol (4.4 grams) was added.

Three more additions of methanol (approximately 4.4 grams each) were subsequently added at about one hour intervals and the reaction mixture was then allowed to warm to room temperature over about 16 hours after the addition of the last methanol charge. The reaction mixture was then cooled in an ice bath to about 1° C. and additional methanol (17.5 grams) was added. The mixture was stirred for 30 minutes and then allowed to warm to room temperature. NOVEC™ 7100 (101 grams) and glacial acetic acid (2.1 grams) were then added to give a mixture having a pH in a range of 6 to 9. Additional acetic acid was added until the pH reached about 5 for a total of 33 grams. Deionized water (200 mL) was then added and the contents of the flask transferred to a separatory funnel. The lower phase was removed and washed with 200 mL water. The lower organic phase was separated, dried over magnesium sulfate, and filtered. The solvent was removed by rotary evaporation to obtain 193 grams of the product alcohol C₃F₇O[CF(CF₃)CF₂O]ₙCF(CF₃)CH₂OH in high purity.

### Preparation 4: Preparation of HFPO-Derived Allyl Ether from HFPO-Derived Alcohol

The HFPO-derived alcohol C₃F₇O[CF(CF₃)CF₂O]ₙCF(CF₃)CH₂OH (M_{N}=5900, 181 grams, 0.031 moles) and NOVEC™ 7200 (360 grams) were placed in a 1 L, three-necked round bottom flask equipped with an overhead stirrer. A solution of potassium hydroxide (4.33 grams, 0.066 moles) in deionized water (7 grams) and tetrabutylammonium bromide (2 grams) were added. The reaction mixture was heated to 63° C. for 30 minutes. Allyl bromide (9.3 grams, 0.076 moles) was then added and the reaction mixture held at 63° C. for about 16 hours. The cooled reaction mixture was then transferred to a separatory funnel and the aqueous phase was separated and discarded. The organic phase was washed with 250 mL of approximately 2N aqueous hydrochloric acid and then with 50 mL of saturated aqueous sodium chloride solution. The lower organic phase was then separated, dried over magnesium sulfate and filtered. Silica gel (15 grams) was then added, the solution agitated briefly, and the silica gel removed by filtration. The solvent was removed by rotary evaporation under vacuum (60° C., 1.3 kPa (10 torr)) to obtain 173 grams of the allyl ether product C₃F₇O[CF(CF₃)CF₂O]ₙCF(CF₃)CH₂OCH₂CH═CH₂ in about 94 weight percent purity which still contained some of the starting material alcohol.

The reaction was repeated with the following changes: 173 grams of the HFPO-derived allyl ether product of 94 percent purity (containing 6 percent of the HFPO-derived alcohol starting material) from the reaction above, NOVEC™ 7200 (347 grams), potassium hydroxide (9.8 grams, 0.149 moles) in deionized water (12.5 grams), tetrabutylammonium bromide (4 grams) and allyl bromide (23.9 grams, 0.195 moles). The reaction was held at 45° C. for 16 hours. The reaction mixture was decanted from a crystalline solid and placed in a separatory funnel. The aqueous layer and a small amount of an upper oily layer removed. The solvent and any excess volatile reagents were removed by rotary evaporation at reduced pressure and the mixture held at 90° C., 10 torr for one hour. The mixture was redissolved in NOVEC™ 7200 (500 mL) and filtered. Silica gel (25 grams) was added and the mixture stirred for 30 minutes. The silica gel was removed by filtration and the solvent removed by rotary evaporation at 65° C., 1.3 kPa (10 torr) to obtain 173 grams of the HFPO-derived allyl ether product that contained no HFPO-derived alcohol starting material.

### Comparative Sample A1: Preparation of HFPO-Derived Thioether Silane (M_{N}=1450)

HFPO-derived thioether silanes were prepared substantially according to the methods described in U.S. Pat. No. 7,294,731 (Flynn et al.), the description of which is incorporated herein by reference. The preparation of the HFPO-derived thioether silane with a number average molecular weight equal to 1450 grams/mole was as follows.

C₃F₇O[CF(CF₃)CF₂O]ₙCF(CF₃)CH₂OCH₂CH═CH₂, (40 grams, 0.028 mole, Mₙ=1250), HSC₃H₆Si(OCH₃)₃(11.1 grams, 0.056 moles, obtained from Alfa Aesar (Ward Hill, Mass., USA)), ethyl acetate (65 mL), NOVEC™ 7100 (65 mL) and 2,2′-azobis(2-methylpropionitrile) (0.13 grams, obtained from E. I. Du Pont de Nemours & Co. (Wilmington, Del., USA) under the trade designation VAZO 64) were combined in a 250 mL round bottom flask equipped with a thermocouple temperature probe, magnetic stir bar and a water filled condenser under a nitrogen atmosphere. The atmosphere in the reaction vessel was then exchanged four times with dry nitrogen using a Firestone valve connected to a water aspirator and a source of dry nitrogen. The reaction mixture was heated to 70° C. and held at that temperature for 16 hours. The solvent was removed by rotary evaporation. Excess silane was removed by distillation (200 mTorr, 40° C.) and PF-5060DL (300 mL) subsequently added. This solution was then washed with acetone (150 mL). The lower fluorochemical phase was separated and the PF-5060DL was removed by rotary evaporation to give 39 grams of the HFPO-derived thioether silane.

### Comparative Sample A2: Preparation of HFPO-Derived Thioether Silane (M_{N}=3300)

The preparation of the HFPO-derived thioether silane with a number average molecular weight equal to 3300 grams/mole was as follows.

C₃F₇O[CF(CF₃)CF₂O]ₙCF(CF₃)CH₂OCH₂CH═CH₂, (15.7 grams, 0.0051 mole, Mₙ=3100), HSC₃H₆Si(OCH₃)₃(4.0 grams, 0.02 moles), ethyl acetate (45 grams), NOVEC™ 7100 (45 grams) and 2,2′-azobis(2-methylpropionitrile) (0.1 grams) were combined in a 250 mL round bottom flask equipped with a thermocouple temperature probe, magnetic stir bar and a water filled condenser under a nitrogen atmosphere. The atmosphere in the reaction vessel was then exchanged four times with dry nitrogen using a Firestone valve connected to a water aspirator and a source of dry nitrogen. The reaction mixture was heated to 63° C. and held at that temperature for 64 hours during which time the reaction became completely homogeneous. The solvents were removed by rotary evaporation and PF-5060DL (350 mL) added. This solution was then washed with acetone (150 mL). The lower fluorochemical phase was separated and subsequently the PF-5060DL was removed by rotary evaporation to give 12.6 grams of the HFPO-derived thioether silane.

### Sample A3: Preparation of HFPO-Derived Thioether Silane (M_{N}=5860)

The preparation of the HFPO-derived thioether silane with a number average molecular weight equal to 5860 grams/mole was as follows.

C₃F₇O[CF(CF₃)CF₂O]ₙCF(CF₃)CH₂OCH₂CH═CH₂, (24.9 grams, 0.0044 mole, Mₙ=5665), HSC₃H₆Si(OCH₃)₃(3.4 grams, 0.018 moles), ethyl acetate (20 grams), NOVEC™ 7200 (80 grams) and 2,2′-azobis(2-methylpropionitrile) (0.3 grams) were combined in a 250 mL round bottom flask equipped with a thermocouple temperature probe, magnetic stir bar and a water filled condenser under a nitrogen atmosphere. The atmosphere in the reaction vessel was then exchanged four times with dry nitrogen using a Firestone valve connected to a water aspirator and a source of dry nitrogen. The reaction mixture was heated to 65° C. and held at that temperature for 16 hours during which time the reaction became completely homogeneous. The solvent was removed by rotary evaporation and PF-5060DL (300 mL) added. This solution was then washed with acetone (150 mL). The lower fluorochemical phase was separated and subsequently the PF-5060DL was removed by rotary evaporation to give 23.7 grams of the HFPO-derived thioether silane. There was still some allyl ether starting material remaining in this reaction so the reaction mixture was dissolved in NOVEC™ 7200 (100 mL) and treated with HSC₃H₆Si(OCH₃)₃(10.0 grams, 0.051 moles) and 2,2′-azobis(2-methylpropionitrile) (0.7 grams) and, after sparging with nitrogen as above, heated to 65° C. and held at that temperature for 16 hours followed by an identical workup to yield the final silane product in which the allyl ether was completely consumed.

### Comparative Sample B1: Preparation of HFPO-Derived Ether Silane (M_{N}=2420)

The HFPO-derived allyl ether C₃F₇O[CF(CF₃)CF₂O]ₙCF(CF₃)CH₂OCH₂CH═CH₂ (M_{N}=2300, 25 grams, 0.0109 moles, prepared substantially as described above for the M_{N}=5900 allyl ether) and 1,3-bis(trifluoromethyl)benzene (50 mL, obtained from TCI America (Portland Oreg., USA)) were placed into a 100 mL round bottom flask equipped with a thermocouple and condenser topped with a glass tee leading to a source of dry nitrogen and a mineral oil bubbler. The reaction solution was then heated to 60° C. and trichlorosilane (6.68 grams, 0.049 moles, obtained from Alfa Aesar (Ward Hill, Mass., USA)) added. Then, platinum(0)-1,3-divinyl-1,1,3,3-tetramethyldisiloxane complex, solution in xylenes (0.15 grams of approximately 2 weight percent Pt, obtained from Aldrich Chemical Company (Milwaukee, Wis., USA)) was added to the solution held at 60° C. in three increments of about 0.05 grams each over a period of two hours. The solution was held at 60° C. for an additional two hours. The homogeneous solution was then cooled to room temperature and the excess silane removed under vacuum. To the remaining mixture was then added a solution of trimethyl orthoformate (14.2 grams, 0.134 mol, obtained from Alfa Aesar (Ward Hill, Mass., USA)) and methanol (0.5 grams). The mixture was heated to 60° C. for sixteen hours. An additional 15 grams of methanol was added and the mixture heated to 60° C. for 45 minutes. The warm solution was transferred to a separatory funnel and cooled to room temperature. The lower phase was separated and the small amount of solvent remaining in the silane was removed by rotary evaporation at reduced pressure (50° C., 2 kPa (15 torr)) to give 20.3 grams of clear HFPO-derived ether silane (M_{N}=2420) C₃F₇O[CF(CF₃)CF₂O]ₙCF(CF₃)CH₂OCH₂CH₂CH₂Si(OMe)₃.

### Sample B2: Preparation of HFPO-Derived Ether Silane (M_{N}=5711)

The HFPO-derived allyl ether prepared as described above C₃F₇O[CF(CF₃)CF₂O]ₙCF(CF₃)CH₂OCH₂CH═CH₂ (M_{N}=5588, 20.4 grams, 0.0037 moles) and 1,3-bis(trifluoromethyl)benzene (50 mL) were placed into a 100 mL round bottom flask equipped with a thermocouple and condenser topped with a glass tee leading to a source of dry nitrogen and a mineral oil bubbler. The reaction solution was then heated to 60° C. and trichlorosilane (5.6 grams, 0.041 moles) added. Then, platinum(0)-1,3-divinyl-1,1,3,3-tetramethyldisiloxane complex, solution in xylenes (0.15 grams of approximately 2 weight percent Pt) was added to the solution in three increments of about 0.05 grams each over a period of three hours. The solution was held at 60° C. for an additional three hours. The homogeneous solution was then cooled to room temperature and the excess silane removed under vacuum. To the remaining mixture was then added a solution of trimethyl orthoformate (10.0 grams, 0.094 moles) and methanol (0.5 grams). The mixture was heated to 60° C. for sixteen hours. An additional 10 grams of methanol was added and the mixture heated to 60° C. for 45 minutes. The warm solution was transferred to a separatory funnel and cooled to room temperature. The lower phase was separated and the small amount of solvent remaining in the silane was removed by rotary evaporation at reduced pressure (50° C., 2 kPa (15 torr)) to give 16.8 grams of clear HFPO-derived ether silane (M_{N}=5711) C₃F₇O[CF(CF₃)CF₂O]ₙCF(CF₃)CH₂OCH₂CH₂CH₂Si(OMe)₃.

### Sample C1: Preparation of HFPO-Derived Ether Silane (M_{N}=7124)

The HFPO-derived allyl ether prepared as described above C₃F₇O[CF(CF₃)CF₂O]ₙCF(CF₃)CH₂OCH₂CH═CH₂ (M_{N}=7002, 43.4 grams, 0.0062 moles) and 1,4-bis(trifluoromethyl)benzene (164 grams, which can be purchased from Alfa Aesar) were placed into a 500 mL round bottom flask equipped with a thermocouple and condenser topped with a glass tee leading to a source of dry nitrogen and a mineral oil bubbler. Trichlorosilane (11.7 grams, 0.086 moles) was added and the reaction solution was then heated to 60° C. Then, platinum(0)-1,3-divinyl-1,1,3,3-tetramethyldisiloxane complex, solution in xylenes (about 0.4 grams of approximately 2 weight percent Pt) was added to the solution and the solution was held at 60° C. for 16 hours. The homogeneous solution was then cooled to room temperature and the excess silane removed under vacuum. To the remaining mixture was then added trimethyl orthoformate (9.1 grams, 0.085 moles) and the mixture was heated to 60° C. for sixteen hours. The solution was transferred to a separatory funnel and methanol (200 mL) added. The lower phase was separated and the small amount of solvent remaining in the silane was removed by rotary evaporation at reduced pressure (50° C., 2 kPa (15 torr)) to give 43.6 grams of clear HFPO-derived ether silane (M_{N}=7124) C₃F₇O[CF(CF₃)CF₂O]ₙCF(CF₃)CH₂OCH₂CH₂CH₂Si(OMe)₃.

### Sample C2: Preparation of HFPO-Derived Ether Silane (M_{N}=14634)

The HFPO-derived allyl ether prepared as described above C₃F₇O[CF(CF₃)CF₂O]ₙCF(CF₃)CH₂OCH₂CH═CH₂ (M_{N}=14500, 37.3 grams, 0.0026 moles) and 1,4-bis(trifluoromethyl)benzene (166 grams) were placed into a 500 mL round bottom flask equipped with a thermocouple and condenser topped with a glass tee leading to a source of dry nitrogen and a mineral oil bubbler. Trichlorosilane (6.76 grams, 0.049 moles) was added and the reaction solution was then heated to 60° C. Then, platinum(0)-1,3-divinyl-1,1,3,3-tetramethyldisiloxane complex, solution in xylenes (about 0.4 grams of approximately 2 weight percent Pt) was added to the solution and the solution was held at 60° C. for 16 hours. The homogeneous solution was then cooled to room temperature and the excess silane removed under vacuum. To the remaining mixture was then added trimethyl orthoformate (5.3 grams, 0.05 moles) and the mixture was heated to 60° C. for sixteen hours. The solution was transferred to a separatory funnel and methanol (200 mL) added. The lower phase was separated and washed two times with methanol (50 mL), the residue taken up in NOVEC™ 7200 and the solvents removed by rotary evaporation at reduced pressure (50° C., 2 kPa (15 torr)) to give 37 grams of clear HFPO-derived ether silane (M_{N}=14634) C₃F₇O[CF(CF₃)CF₂O]ₙCF(CF₃)CH₂OCH₂CH₂CH₂Si(OMe)₃.

### Example 9: Comparative Samples A1 and A2 and Sample A3

All samples described below were coated on float glass substrates that were cleaned, cured and tested according to the methods described above (deposition method) unless otherwise noted. Samples were cleaned according to the second method described above.

For Comparative Sample A1 (CS A1), a cleaned float glass plate substrate was spray-coated with a solution of 2.5 grams of a 20 weight percent solution of HFPO-derived thioether silane (MW 1450) in NOVEC™ 7200 diluted to a total weight of 20 grams with NOVEC™ 7300.

For Comparative Sample A2 (CS A2), a cleaned float glass plate substrate was spray-coated with a solution of 2.5 grams of a 20 weight percent solution of HFPO-derived thioether silane (MW 3300) in NOVEC™ 7200 diluted to a total weight of 20 grams with NOVEC™ 7300.

For Sample A3, a cleaned float glass plate substrate was spray-coated with a solution of 2.5 grams of a 20 weight percent solution of HFPO-derived thioether silane (MW 5860) in NOVEC™ 7200 diluted to a total weight of 20 grams with NOVEC™ 7300.

All samples of Comparative Samples A1 and A2 and Sample A3 were cured at 135° C. for 10 minutes. After resting, the samples were cleaned and initial contact angle measurements were performed. The samples were then abraded according to the first abrasion test method described above. Contact angle measurements were performed after each 1000 cycles of abrasion testing as described above. The test results are summarized in Table 5 below.

TABLE 5

| | 0 | 2500 | 5000 | 7500 | 10000 |
|---|---|---|---|---|---|
| | H₂O Contact Angle (Degrees) after Abrasion Cycles | | | | |
| CS A1 | 111.1 | 108.5 | 99.7 | 96.8 | 80.5 |
| CS A2 | 115.1 | 114.4 | 110.4 | 103 | 79.6 |
| A3 | 115.7 | 114.7 | 110.3 | 107.6 | 90.3 |
| | HD Contact Angle (Degrees) after Abrasion Cycles | | | | |
| CS A1 | 74.5 | 70.6 | 68 | 58.7 | 46.3 |
| CS A2 | 69.4 | 74.6 | 74.9 | 67.3 | 62.5 |
| A3 | 68.1 | 71.6 | 70.7 | 68.7 | 69.4 |

Table 5 shows that upon completion of 10,000 cycles, the water and HD contact angles for Comparative Sample A1 and A2 dropped significantly compared to those values for Sample A3 which were maintained most of the coating performance at the completion of the test.

### Example 10: Comparative Sample B1 and Sample B2

All samples described below were coated on float glass substrates that were cleaned, cured and tested according the methods described above (deposition method) unless otherwise noted. Samples were cleaned according to the second method as described above.

For Comparative Sample B1 (CS B1), a cleaned float glass plate substrate was spray-coated with a solution of 2.5 grams of a 20 weight percent solution of HFPO-derived ether silane (MW 2420) in NOVEC™ 7200 diluted to a total weight of 20 grams using NOVEC™ 7300.

For Sample B2, a cleaned float glass plate substrate was spray-coated with a solution of 2.5 grams of a 20 weight percent solution of HFPO-derived ether silane (MW 5711) in NOVEC™ 7200 diluted to a total weight of 20 grams with NOVEC™ 7300.

All samples were cured at 185° C. for 60 minutes. After resting, the samples were cleaned and initial contact angle measurements were performed. The samples were then abraded according to abrasion test method two as described above. Contact angle measurements were performed after each 1000 cycles of abrasion testing as described above. The test results are summarized in Table 6 below.

TABLE 6

| | 0 | 1000 | 2000 | 3000 |
|---|---|---|---|---|
| | H₂O Contact Angle (Degrees) after Abrasion Cycles | | | |
| CS B1 | 116.2 | 114.5 | 45.0 | 45.0 |
| B2 | 117.3 | 113.8 | 111.3 | 103.7 |
| | HD Contact Angle (Degrees) after Abrasion Cycles | | | |
| CS B1 | 73.0 | 71.0 | 15.0 | 15.0 |
| B2 | 73.1 | 72.0 | 68.5 | 68.4 |

Table 6 shows that at the completion of 2000 cycles, CS B1 had complete failure of the coating represented by the water contact angle of 45 degrees and the HD contact angle of 15 degrees. These values are consistent with contact angles on uncoated glass. After 3000 cycles, B2 showed a minimal drop in contact angle.

### Example 11: Samples C1 and C2

All samples described below were coated on chemically strengthened glass substrates that were cleaned, cured and tested according the methods described above (liquid deposition) unless otherwise noted. Samples were cleaned according to method 1 followed by method 3 as described above.

For Sample C1, a cleaned chemically strengthened glass plate substrate was spray-coated with a solution of 2.5 grams of a 20 weight percent solution of HFPO-derived ether silane (MW 7124) in NOVEC™ 7200 diluted to a total weight of 20 grams using NOVEC™ 7300.

For Sample C2, a cleaned chemically strengthened glass plate substrate was spray-coated with a solution of 2.5 grams of a 20 weight percent solution of HFPO-derived ether silane (MW 14634) in NOVEC™ 7200 diluted to a total weight of 20 grams with NOVEC™ 7300.

All samples of C1 and C2 were cured at 185° C. for over 60 minutes. After resting, the samples were cleaned and initial contact angle measurements were performed. The samples were then abraded according to abrasion test method two as described above. Contact angle measurements were performed after the first 2000 cycles and then after completing 3000 cycles of abrasion testing as described above. The test results are summarized in Table 7 below.

TABLE 7

| | 0 | 2000 | 3000 |
|---|---|---|---|
| | H₂O Contact Angle (Degrees) after Abrasion Cycles | | |
| C1 | 118.8 | 105.2 | 98.7 |
| C2 | 116.0 | 113.1 | 107.0 |
| | HD Contact Angle (Degrees) after Abrasion Cycles | | |
| C1 | 72.1 | 66.6 | 63.6 |
| C2 | 77.8 | 71.8 | 70.1 |

Table 7 shows at the completion of 3000 cycles, both Samples C1 and C2 had minimal drops in the water contact angle and the HD contact angles. Table 7 also shows that increased molecular weight resulted in improved coating durability.

### Example 12: Comparative Samples 4A and 4B and Sample 4C

All samples described below were coated on cleaned float glass substrates, cured and tested according the methods described above (liquid deposition) unless otherwise noted.

Comparative Sample 4A (CS 4A) was uncoated float glass.

Comparative Sample 4B (CS 4B) was coated with a solution of 2.5 grams of a 20 weight percent solution of HFPO-derived ether silane (MW 2420) in NOVEC™ 7200 diluted to a total weight of 20 grams with NOVEC™ 7300.

Sample 4C was coated with a solution of 2.5 grams of a 20 weight percent solution of HFPO-derived ether silane (MW 5711) in NOVEC™ 7200 diluted to a total weight of 20 grams with NOVEC™ 7300.

Sample 4D was coated with a solution of 2.5 grams of a 20 weight percent solution of HFPO-derived ether silane (MW 7112) in NOVEC™ 7200 diluted to a total weight of 20 grams with NOVEC™ 7300.

The coated glass substrates of Comparative Sample 4B and Samples 4C and 4D were then cured at 185° C. for 60 minutes. After cooling for 30 minutes, the coated glass substrates were placed in a controlled temperature and humidity room to age for 3 days. The coefficient of friction was measured and reported in Table 8.

TABLE 8

| | CoF (unitless) |
|---|---|
| CS 4A | 0.55 |
| CS 4B | 0.35 |
| 4C | 0.30 |
| 4D | 0.28 |

Table 8 shows that the coefficient of friction was altered by applying coatings with different molecular weights. Uncoated float glass had the highest CoF while coated float glass had a lower (and more desirable) CoF. A suitable CoF on float glass is less than about 0.35.

### Plasma Deposition of the Silicon Containing DLG Tie-Layer:

Sapphire and Nickel substrates were plasma treated to deposit the DLG film using apparatus and procedures of generally similar type to those described in Example 9 of U.S. Pat. No. 7,125,603, which is incorporated by reference herein in its entirety. The substrate were subjected to a preliminary plasma treatment of O2 alone (without any tetramethylsilane (TMS) being present) at a flow rate of 500 std.cm3/min and power of 500 watts for four minutes. Immediately after the oxygen plasma cleaning step, tetramethylsilane vapor was introduced into the chamber to deposit the DLC film at a flow rate of 150 standard cm3/min and the oxygen flow was maintained at 500 sccm. The plasma power conditions were maintained the same at 500 watts and the DLG deposition step was continued for 4 seconds. After this, the TMS flow was disabled and the plasma continued to operate with pure oxygen gas at 500 standard cm3/min and 500 watts for an additional minute. After this, the plasma power was disabled, the gases shut off and the chamber vented to atmospheric pressure. The substrates were removed from the chamber upon venting.

### Application of the Topical Coating on the DLG Tie-Layer:

After deposition of the silicon containing DLG tie-layer to one face of the sapphire and nickel disks, the samples were immersed for 10 seconds in three different types of solutions as follows:

Solution 1: EGC 1720—This is a commercial product available from 3M Company (Saint Paul, Minn.) as Novec EGC 1720, and contains the perfluoropolyether (PFPE) amido silane active compound, this chemistry was disclosed in prior issued U.S. Pat. No. 8,158,264, which is incorporated herein by reference in its entirety.
Solution 2: Novec 2202—This is a commercial new product available from 3M Company (Saint Paul, Minn.) as Novec 2202, and contains the new chemical, hexafluoropropyleneoxide (HFPO) ether silane having a molecular weight of 8K, this new chemistry was disclosed as nominally in example C1 in published patent application WO 2013126208A, which is incorporated by reference herein in its entirety, but the average molecular weight was slightly higher, at 8K, with the tail of its distribution reaching up to 7K.
Solution 3: GP913—This is available as a commercial product from Genesee Polymers Corporation (Burton, Mich.) and contains a ethoxy functional polydimethylsiloxane, and diluted in toluene to a 0.1% concentration.

### Hot Water Immersion Test:

500 ml of distilled water was added to a 1000 ml glass beaker and heated on a hot plate and stirred with a magnetic stirrer. After the temperature of the water bath reached 95 degrees Centigrade, the coated samples were dropped into the beaker and allowed to remain in the beaker for 30 minutes. After 30 minutes, the samples were removed and allowed to cool down. The presence of the fluorochemical layer was determined by writing on the coated surface with a Sharpie permanent marker. Results of the test are summarized in the slide below.

### Internal Combustion Engine Component Embodiments

1. A component of an internal combustion engine with anti-fouling (e.g., anti-coking) properties, said component comprising:
a metal surface;
a plasma deposition formed layer comprising silicon, oxygen, and hydrogen on at least a portion of said metal surface; and
an anti-fouling coating, of an at least partially fluorinated composition comprising at least one silane group, on at least a portion of a surface of said layer.
   2. The component of embodiment 1, wherein said layer is formed by ionizing a gas comprising at least one of an organosilicon or a silane compound.
   3. The component of embodiment 2, wherein the silicon of the at least one of an organosilicon or silane compound is present in an amount of at least about 5 atomic percent of the gas, based on the total atomic weight of the gas.
   4. The component of embodiment 2 or 3, wherein the gas comprises the organosilicon.
   5. The component of embodiment 4, wherein the organosilicon comprises tetramethylsilane.
   6. The component of any one of embodiments 1 through 5, wherein said layer further comprises carbon.
   7. The component of embodiment 2 or embodiment 3, wherein the gas comprises the silane compound.
   8. The component of embodiment 7, wherein the silane compound comprises SiH₄.
   9. The component of any one of embodiments 2 through 8, wherein the gas further comprises oxygen.
   10. The component of embodiment 9, wherein the gas further comprises at least one of argon, ammonia, hydrogen, and nitrogen.
   11. The component of embodiment 10, wherein the gas further comprises at least one of ammonia, hydrogen, and nitrogen, such that the total amount of the at least one of ammonia, hydrogen, and nitrogen is at least about 5 molar percent and not more than about 50 molar percent of the gas.
   12. The component of any one of embodiments 1 through 11, wherein the plasma deposition of said layer is carried out for a period of time not less than about 5 seconds and not more than about 15 seconds.
   13. The component of embodiment 12, wherein the period of time is about 10 seconds.
   14. The component of any one of embodiments 1 through 13, wherein said metal surface is exposed to an oxygen plasma prior to the plasma deposition of said layer.
   15. The component of any one of embodiments 1 through 14, wherein said layer is exposed to an oxygen plasma.
   16. The component of any one of embodiments 1 through 15, wherein the at least partially fluorinated composition comprising at least one silane group is a polyfluoropolyether silane.
   17. The component of embodiment 16, wherein the polyfluoropolyether silane is of the Formula Ia:

R_{f}[Q′-C(R)₂—Si(Y′)₃₋ₓ(R^{1a})ₓ]_{z} Ia

wherein:
R_{f} is a monovalent or multivalent polyfluoropolyether segment;
Q′ is an organic divalent linking group;
each R is independently hydrogen or a C₁₋₄ alkyl group;
each Y′ is a hydrolysable group independently selected from the group consisting of halogen, alkoxy, acyloxy, polyalkyleneoxy, and aryloxy groups;
R^{1a} is a C₁₋₈ alkyl or phenyl group;
x is 0 or 1 or 2; and
z is 1, 2, 3, or 4.
   18. The component of embodiment 17, wherein the polyfluoropolyether segment, R_{f}, comprises perfluorinated repeating units selected from the group consisting of —(CₙF₂ₙO)—, —(CF(Z)O)—, —(CF(Z)CₙF₂ₙO)—, —(CₙF₂ₙCF(Z)O)—, —(CF₂CF(Z)O)—, and combinations thereof; and wherein Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted; and n is an integer from 1 to 12.
   19. The component of embodiment 17 or embodiment 18, wherein z is 2, and R_{f} is selected from the group consisting of —CF₂O(CF₂O)ₘ(C₂F₄O)ₚCF₂—, —CF(CF₃)—(OCF₂CF(CF₃))ₚO—R_{f}′—O(CF(CF₃)CF₂O)ₚCF(CF₃)—, —CF₂O(C₂F₄O)_{P}CF₂—, and —(CF₂)₃O(C₄F₈O)ₚ(CF₂)₃—, and wherein R_{f} is a divalent, perfluoroalkylene group containing at least one carbon atom and interrupted in chain by O or N, m is 1 to 50, and p is 3 to 40.
   20. The component of embodiment 19, wherein R_{f} is —CF₂O(CF₂O)ₘ(C₂F₄O)ₚCF₂—, and Q′-C(R)₂—Si(Y′)₃₋ₓ(R^{1a})ₓ is C(O)NH(CH₂)₃Si(OR′)₃, wherein R′ is methyl or ethyl.
   21. The component of any one of embodiments 1 through 15, wherein the at least partially fluorinated composition comprising at least one silane group further comprises an organic solvent.
   22. The component of any one of embodiments 16 through 20, wherein the polyfluoropolyether silane is applied as a composition comprising the polyfluoropolyether silane and an organic solvent.
   23. The component of embodiment 21 or embodiment 22, wherein the organic solvent is a fluorinated solvent.
   24. The component of embodiment 21 or embodiment 22, wherein the solvent is a lower alcohol.
   25. The component of embodiment 24, wherein the at least partially fluorinated composition comprising at least one silane group further comprises an acid.
   26. The component of any one of embodiments 1 through 15, with the at least partially fluorinated composition comprising at least one silane group of any one of embodiments 16 through 20, wherein the polyfluoropolyether silane is applied by chemical vapor deposition.
   27. The component of any one of embodiments 1 through 15, 21, and embodiments 23, 24, and 25 as dependent on embodiment 21, wherein said component is subjected to an elevated temperature after said anti-fouling coating is applied.
   28. The component of any one of embodiments 16 through 20, 22, embodiments 23, 24, and 25 as dependent on embodiment 22, and embodiment 26, wherein said component is subjected to an elevated temperature after the polyfluoropolyether silane is applied.
   29. The component of embodiment 25, wherein said component is dried at a temperature in the range of from about 15° C. up to and including about 30° C., after said anti-fouling coating is applied.
   30. The component of any one of embodiments 1 through 29, wherein said layer comprises at least 10 atomic percent silicon, at least 10 atomic percent oxygen, and at least 5 atomic percent hydrogen, wherein all atomic percent values are based on the total atomic weight of said layer, and said anti-fouling coating is a polyfluoropolyether-containing coating comprising polyfluoropolyether silane groups of the following Formula Ib:

R_{f}[Q′-C(R)₂—Si(O—)₃₋ₓ(R^{1a})ₓ]_{z} Ib

which shares at least one covalent bond with said layer; and

wherein:
R_{f} is a monovalent or multivalent polyfluoropolyether segment;
Q′ is an organic divalent linking group;
each R is independently hydrogen or a C₁₋₄ alkyl group;
R^{1a} is a C₁₋₈ alkyl or phenyl group;
x is 0 or 1 or 2; and
z is 1, 2, 3, or 4.
   31. The component of embodiment 30, wherein said layer comprises at least about 20 atomic percent silicon, based on the total atomic weight of said layer.
   32. The component of embodiment 30 or embodiment 31, wherein said layer further comprises at least about 15 atomic percent oxygen, based on the total atomic weight of said layer.
   33. The component of any one of embodiments 30 through 32, wherein said layer further comprises at least one of carbon or nitrogen such that the total atomic content of the at least one of carbon or nitrogen is at least 5 atomic percent, based on the total atomic weight of said layer.
   34. The component of embodiment 33, wherein said layer further comprises carbon such that the total atomic content of the carbon is at least 5 atomic percent, based on the total atomic weight of said layer.
   35. The component of any one of embodiments 30 through 34, wherein the thickness of said layer is at least about 0.5 nanometer and not more than about 100 nanometers.
   36. The component of embodiment 35, wherein the thickness of said layer is at least about 1 nanometer and not more than about 10 nanometers.
   37. The component of any one of embodiments 30 through 36, wherein the polyfluoropolyether segment, R_{f}, includes perfluorinated repeating units selected from the group consisting of —(CₙF₂ₙO)—, —(CF(Z)O)—, —(CF(Z)CₙF₂ₙO)—, —(CₙF₂ₙCF(Z)O)—, —(CF₂CF(Z)O)—, and combinations thereof; and wherein Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted; and n is an integer from 1 to 12.
   38. The component of any one of embodiments 30 through 36, wherein z is 2, and R_{f} is selected from the group consisting of —CF₂O(CF₂O)ₘ(C₂F₄O)ₚCF₂—, —CF(CF₃)—(OCF₂CF(CF₃))ₚO—R_{f}′—O(CF(CF₃)CF₂O)ₚCF(CF₃)—, —CF₂O(C₂F₄O)ₚCF₂—, and —(CF₂)₃O(C₄F₈O)ₚ(CF₂)₃—, and wherein R_{f}′ is a divalent, perfluoroalkylene group containing at least one carbon atom and optionally interrupted in chain by O or N, m is 1 to 50, and p is 3 to 40.
   39. The component of embodiment 38, wherein R_{f} is —CF₂O(CF₂O)ₘ(C₂F₄O)ₚCF₂—, and Q-C(R)₂—Si(Y)₃₋ₓ(R¹)ₓ is C(O)NH(CH₂)₃Si(OR¹)₃, wherein R¹ is methyl or ethyl.
   40. The component of any one of embodiments 1 through 29 or the component of any one of embodiments 30 through 39, wherein said metal surface comprises a hard surface.
   41. The component of any one of embodiments 1 through 40, wherein said metal surface comprises chromium or a chromium alloy.
   42. The component of any one of embodiments 1 through 41, wherein said anti-fouling coating comprises:

a hexafluoropropylene oxide derived silane polymer having a molecular weight of greater than about 5500,

wherein said anti-fouling coating has (a) a water contact angle that decreases by less than about 27% after 10000 abrasion cycles, (b) a thickness of between about 2 and about 15 nanometers, and (c) a coefficient of friction constant of less than about 0.35.

43. The component of embodiment 42, wherein the water contact angle of said anti-fouling coating decreases by less than about 25% after 10000 abrasion cycles.
44. The component of embodiment 42 or 43, wherein a hexadecane contact angle of said anti-fouling coating decreases by less than about 8% after 10000 abrasion cycles.
45. The component of embodiment 42 or 43, wherein a hexadecane contact angle of said anti-fouling coating decreases by less than about 6% after 10000 abrasion cycles.
46. The component of any one of embodiments 42 through 45, wherein said anti-fouling coating has a coefficient of friction constant of less than about 0.32.
47. The component of any one of embodiments 42 through 46, wherein the molecular weight of said anti-fouling coating is based on a single molecular weight.
48. The component of any one of embodiments 42 through 46, wherein the molecular weight of said anti-fouling coating is based on more than one molecular weight.
49. The component of any one of embodiments 1 through 48, wherein said component is a fuel injector nozzle, fuel injector body, intake valve, intake tract, exhaust valve, valvetrain component (e.g., rocker arm, valve lifter, etc.), exhaust head tract, cooling system, oil passage, piston (e.g., piston crown, piston bowl, etc.), combustion chamber surfaces, gas recirculation (EGR) component (e.g., EGR valve), or air/oil separator.

### Internal Combustion Engine Embodiment

50. An internal combustion engine comprising the component of any one of embodiments 1 through 49.

### Method of Making Embodiments

51. A method of making the component of any one of embodiments 1 through 49, the method comprising:

forming a layer comprising silicon, oxygen, and hydrogen on at least a portion of the metal surface of the component by plasma deposition; and

applying an at least partially fluorinated composition comprising at least one silane group to at least a portion of a surface of the layer comprising the silicon, oxygen, and hydrogen.

52. The method of embodiment 51, wherein forming the layer comprising the silicon, oxygen, and hydrogen comprises ionizing a gas comprising at least one of an organosilicon or a silane compound.
53. The method of embodiment 52, wherein the silicon of the at least one of an organosilicon or silane compound is present in an amount of at least about 5 atomic percent of the gas, based on the total atomic weight of the gas.
54. The method of embodiment 52 or embodiment 53, wherein the gas comprises the organosilicon.
55. The method of embodiment 54, wherein the organosilicon comprises tetramethylsilane.
56. The method of any one of embodiments 51 through 55, wherein the layer comprising the silicon, oxygen, and hydrogen further comprises carbon.
57. The method of embodiment 52 or embodiment 53, wherein the gas comprises the silane compound.
58. The method of embodiment 57, wherein the silane compound comprises SiH₄.
59. The method of any one of embodiments 52 through 58, wherein the gas further comprises oxygen.
60. The method of embodiment 59, wherein the gas further comprises at least one of argon, ammonia, hydrogen, and nitrogen.
61. The method of embodiment 60, wherein the gas further comprises at least one of ammonia, hydrogen, and nitrogen, such that the total amount of the at least one of ammonia, hydrogen, and nitrogen is at least about 5 molar percent and not more than about 50 molar percent of the gas.
62. The method of any one of embodiments 51 through 61, wherein the plasma deposition of the layer comprising the silicon, oxygen, and hydrogen is carried out for a period of time not less than about 5 seconds and not more than about 15 seconds.
63. The method of embodiment 62, wherein the period of time is about 10 seconds.
64. The method of any one of embodiments 51 through 63, wherein the metal surface is exposed to an oxygen plasma prior to the plasma deposition of the layer comprising the silicon, oxygen, and hydrogen.
65. The method of any one of embodiments 51 through 64, wherein the layer comprising the silicon, oxygen, and hydrogen is exposed to an oxygen plasma.
66. The method of any one of embodiments 51 through 65, wherein the at least partially fluorinated composition comprising at least one silane group is a polyfluoropolyether silane.
67. The method of embodiment 66, wherein the polyfluoropolyether silane is of the Formula Ia:

R_{f}[Q′-C(R)₂—Si(Y′)₃₋ₓ(R^{1a})ₓ]_{z} Ia

wherein:
R_{f} is a monovalent or multivalent polyfluoropolyether segment;
Q′ is an organic divalent linking group;
each R is independently hydrogen or a C₁₋₄ alkyl group;
each Y′ is a hydrolysable group independently selected from the group consisting of halogen, alkoxy, acyloxy, polyalkyleneoxy, and aryloxy groups;
R^{1a} is a C₁₋₈ alkyl or phenyl group;
x is 0 or 1 or 2; and
z is 1, 2, 3, or 4.
   68. The method of embodiment 67, wherein the polyfluoropolyether segment, R_{f}, comprises perfluorinated repeating units selected from the group consisting of —(CₙF₂ₙO)—, —(CF(Z)O)—, —(CF(Z)CₙF₂ₙO)—, —(CₙF₂ₙCF(Z)O)—, —(CF₂CF(Z)O)—, and combinations thereof; and wherein Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted; and n is an integer from 1 to 12.
   69. The method of embodiment 67 or embodiment 68, wherein z is 2, and R_{f} is selected from the group consisting of —CF₂O(CF₂O)ₘ(C₂F₄O)ₚCF₂—, —CF(CF₃)—(OCF₂CF(CF₃))ₚO—R_{f}′—O(CF(CF₃)CF₂O)ₚCF(CF₃)—, —CF₂O(C₂F₄O)ₚCF₂—, and —(CF₂)₃O(C₄F₈O)ₚ(CF₂)₃—, and wherein R_{f}′ is a divalent, perfluoroalkylene group containing at least one carbon atom and interrupted in chain by O or N, m is 1 to 50, and p is 3 to 40.
   70. The method of embodiment 69, wherein R_{f} is —CF₂O(CF₂O)ₘ(C₂F₄O)ₚCF₂—, and Q′-C(R)₂—Si(Y′)₃₋ₓ(R^{1a})ₓ is C(O)NH(CH₂)₃Si(OR′)₃, wherein R′ is methyl or ethyl.
   71. The method of any one of embodiments 51 through 65, wherein the at least partially fluorinated composition comprising at least one silane group further comprises an organic solvent.
   72. The method of any one of embodiments 66 through 70, wherein the polyfluoropolyether silane is applied as a composition comprising the polyfluoropolyether silane and an organic solvent.
   73. The method of embodiment 71 or embodiment 72, wherein the organic solvent is a fluorinated solvent.
   74. The method of embodiment 71 or embodiment 72, wherein the solvent is a lower alcohol.
   75. The method of embodiment 74, wherein the composition further comprises an acid.
   76. The method of any one of embodiments 51 through 65, with the at least partially fluorinated composition comprising at least one silane group of embodiments 66 through 70, wherein the polyfluoropolyether silane is applied by chemical vapor deposition.
   77. The method of any one of embodiments 51 through 65, 71, and embodiments 73, 74, and
   75 as dependent on embodiment 71, further comprising subjecting the metal surface to an elevated temperature after applying the at least partially fluorinated composition comprising at least one silane group.
   78. The method of any one of embodiments 66 through 70, 72, embodiments 73, 74, and 75 as dependent on embodiment 72, and embodiment 76, further comprising the step of subjecting the metal surface to an elevated temperature after applying the polyfluoropolyether silane.
   79. The method of embodiment 75, further comprising the step of allowing the metal surface to dry at a temperature of about 15° C. to about 30° C. after applying the composition.

The complete disclosures of the patents, patent documents and publications cited herein are incorporated by reference in their entirety as if each were individually incorporated. In case of conflict, the present specification, including definitions, shall control. Various modifications and alterations to this invention will become apparent to those skilled in the art without departing from the scope and spirit of this invention. Illustrative embodiments and examples are provided as examples only and are not intended to limit the scope of the present invention. The scope of the invention is limited only by the claims set forth as follows.

1. A component of an internal combustion engine with anti-fouling (e.g., anti-coking) properties, said component comprising:
a metal surface;
a plasma deposition formed layer comprising silicon, oxygen, and hydrogen on at least a portion of said metal surface; and
an anti-fouling coating, of an at least partially fluorinated composition comprising at least one silane group, on at least a portion of a surface of said layer.

2. The component of claim 1, wherein said layer is formed by ionizing a gas comprising at least one of an organosilicon or a silane compound.

3. The component of claim 1, wherein said metal surface is exposed to an oxygen plasma prior to the plasma deposition of said layer.

4. The component of claim 1, wherein the at least partially fluorinated composition comprising at least one silane group is a polyfluoropolyether silane of the Formula Ia:
R_{f}[Q′-C(R)₂—Si(Y′)₃₋ₓ(R^{1a})ₓ]_{z} Ia
wherein:
R_{f} is a monovalent or multivalent polyfluoropolyether segment;
Q′ is an organic divalent linking group;
each R is independently hydrogen or a C₁₋₄ alkyl group;
each Y′ is a hydrolysable group independently selected from the group consisting of halogen, alkoxy, acyloxy, polyalkyleneoxy, and aryloxy groups;
R^{1a} is a C₁₋₈ alkyl or phenyl group;
x is 0 or 1 or 2; and
z is 1, 2, 3, or 4.

5. The component of claim 4, wherein the polyfluoropolyether segment, R_{f}, comprises perfluorinated repeating units selected from the group consisting of —(CₙF₂ₙO)—, —(CF(Z)O)—, —(CF(Z)CₙF₂ₙO)—, —(CₙF₂ₙCF(Z)O)—, —(CF₂CF(Z)O)—, and combinations thereof; and wherein Z is a perfluoroalkyl group, an oxygen-containing perfluoroalkyl group, a perfluoroalkoxy group, or an oxygen-substituted perfluoroalkoxy group, each of which can be linear, branched, or cyclic, and have 1 to 9 carbon atoms and up to 4 oxygen atoms when oxygen-containing or oxygen-substituted; and n is an integer from 1 to 12.

6. The component of claim 1, wherein said component is subjected to an elevated temperature after said anti-fouling coating is applied.

7. The component of claim 1, wherein the at least partially fluorinated composition comprising at least one silane group further comprises an organic solvent, the at least partially fluorinated composition comprising at least one silane group further comprises an acid, and said component is dried at a temperature in the range of from about 15° C. up to and including about 30° C., after said anti-fouling coating is applied.

8. The component of claim 1, wherein said layer comprises at least 10 atomic percent silicon, at least 10 atomic percent oxygen, and at least 5 atomic percent hydrogen, wherein all atomic percent values are based on the total atomic weight of said layer, and said anti-fouling coating is a polyfluoropolyether-containing coating comprising polyfluoropolyether silane groups of the following Formula Ib:
R_{f}[Q′-C(R)₂—Si(O—)₃₋ₓ(R^{1a})ₓ]_{z} Ib
which shares at least one covalent bond with said layer; and
wherein:
R_{f} is a monovalent or multivalent polyfluoropolyether segment;
Q′ is an organic divalent linking group;
each R is independently hydrogen or a C₁₋₄ alkyl group;
R^{1a} is a C₁₋₈ alkyl or phenyl group;
x is 0 or 1 or 2; and
z is 1, 2, 3, or 4.

9. The component of claim 8, wherein said layer further comprises at least one of carbon or nitrogen such that the total atomic content of the at least one of carbon or nitrogen is at least 5 atomic percent, based on the total atomic weight of said layer.

10. The component of claim 1, wherein said metal surface comprises chromium or a chromium alloy.

11. The component of claim 1, wherein said anti-fouling coating comprises:
a hexafluoropropylene oxide derived silane polymer having a molecular weight of greater than about 5500,
wherein said anti-fouling coating has (a) a water contact angle that decreases by less than about 27% after 10000 abrasion cycles, (b) a thickness of between about 2 and about 15 nanometers, and (c) a coefficient of friction constant of less than about 0.35.

12. The component of claim 1, wherein said component is a fuel injector nozzle, fuel injector body, intake valve, intake tract, exhaust valve, valvetrain component, exhaust head tract, cooling system component, oil passage, piston, combustion chamber, EGR component, or air/oil separator.

13. An internal combustion engine comprising the component of claim 1.

14. A method of making the component of claim 1, the method comprising:
forming a layer comprising silicon, oxygen, and hydrogen on at least a portion of the metal surface of the component by plasma deposition; and
applying an at least partially fluorinated composition comprising at least one silane group to at least a portion of a surface of the layer comprising the silicon, oxygen, and hydrogen.

15. The method of claim 14, wherein forming the layer comprising the silicon, oxygen, and hydrogen comprises ionizing a gas comprising at least one of an organosilicon or a silane compound.
